(19) United States
(12) Patent Application Publication
(10) Pub. No.: US 2023/0263016 A1
(43) Pub. Date: Aug. 17, 2023

(54) DISPLAY DEVICE AND METHOD FOR MANUFACTURING ORGANIC ELECTROLUMINESCENT DISPLAY PANEL

(71) Applicant: Japan Display Inc., Tokyo (JP)

(72) Inventors: Hiroumi KINJO, Tokyo (JP); Hayata AOKI, Tokyo (JP); Jun NITTA, (US)

(73) Assignee: Japan Display Inc., Tokyo (JP)

(21) Appl. No.: 18/307,393

(22) Filed: Apr. 26, 2023

Related U.S. Application Data
(63) Continuation of application No. PCT/JP2021/029969, filed on Aug. 17, 2021.

(30) Foreign Application Priority Data
Nov. 6, 2020 (JP) 2020-185929

(51) Int. Cl. H10K 59/122; H10K 59/12; H10K 71/20

(52) U.S. Cl. CPC H10K 59/122; H10K 59/1201; H10K 71/233

(57) ABSTRACT

According to an aspect, a display device includes: a substrate; a planarization layer provided on the substrate; a plurality of electrodes provided on the planarization layer and arrayed in a first direction and a second direction; a bank provided on the planarization layer and the electrodes and formed in a grid pattern so as to surround each of the electrodes; and a light-emitting layer provided on the electrodes. The bank protrudes with respect to the electrodes in a third direction orthogonal to the first direction and the second direction, and a cutout is formed in part of the bank.

### CROSS-REFERENCE TO RELATED APPLICATIONS

This application claims the benefit of priority from Japanese Patent Application No. 2020-185929 filed on Nov. 6, 2020 and International Patent Application No. PCT/JP2021/029969 filed on Aug. 17, 2021, the entire contents of which are incorporated herein by reference.

### BACKGROUND

### 1. Technical Field

What is disclosed herein relates to a display device and a method for manufacturing an organic electroluminescent display panel.

### 2. Description of the Related Art

As described in Japanese Patent Application Laid-open Publication No. 2016-212979, organic light-emitting diodes (OLED) are known to be mounted using a bank to separate pixels that can be individually controlled to be lit up.

One of the methods for manufacturing a display panel, such as OLED, is photolithography. If a developer used for photolithography remains on the display panel, it may possibly damage a gate array and a light-emitting layer provided to the display panel. For this reason, it is common to prevent the developer from remaining by washing the surface of the display panel after development and removing a residual solution remaining on the display panel after washing. The bank surrounding a pixel electrode, however, has a three- dimensional structure thicker than the pixel electrode. As a result, the solution inside the bank is blocked by the bank, making it difficult to remove the solution to be removed.

For the foregoing reasons, there is a need for a display device that can more readily remove a solution and a method for manufacturing an organic electroluminescent display panel that can more readily remove a solution.

### SUMMARY

According to an aspect, a display device includes: a substrate; a planarization layer provided on the substrate; a plurality of electrodes provided on the planarization layer and arrayed in a first direction and a second direction; a bank provided on the planarization layer and the electrodes and formed in a grid pattern so as to surround each of the electrodes; and a light-emitting layer provided on the electrodes. The bank protrudes with respect to the electrodes in a third direction orthogonal to the first direction and the second direction, and a cutout is formed in part of the bank.

### BRIEF DESCRIPTION OF THE DRAWINGS

FIG. 1 is a sectional view of an example of a multilayered structure of a display device;

FIG. 2 is a plan view of an example of the positional relation of the structures of a planarization layer, electrodes, a bank, and organic EL layers in Dx-Dy plane view;

FIG. 3 is a sectional view along line A-A of FIG. 2;

FIG. 4 is a sectional view along line B-B of FIG. 2;

FIG. 5 is a sectional view along line C-C of FIG. 2;

FIG. 6 is a sectional view along line D-D of FIG. 2;

FIG. 7 is a process diagram illustrating steps for processing components stacked on the planarization layer;

FIG. 8 is a process diagram illustrating steps for processing the components stacked on the planarization layer;

FIG. 9 is a process diagram illustrating steps for processing the components stacked on the planarization layer;

FIG. 10 is a perspective view of a bank structure of the display device according to a reference example;

FIG. 11 is a schematic view illustrating how the bank prevents removal of a solution;

FIG. 12 is a sectional view along line B-B according to a second embodiment;

FIG. 13 is a sectional view along line D-D according to the second embodiment;

FIG. 14 is a schematic view of the shape of the bank according to the first embodiment;

FIG. 15 is a schematic view of the shape of the bank according to the second embodiment;

FIG. 16 is a schematic view of the shape of the bank according to the reference example;

FIG. 17 is a sectional view along line A-A according to a third embodiment;

FIG. 18 is a sectional view along line B-B according to the third embodiment;

FIG. 19 is a sectional view along line C-C according to the third embodiment;

FIG. 20 is a sectional view along line D-D according to the third embodiment;

FIG. 21 is a process diagram illustrating steps for processing the components stacked on a lower planarization layer;

FIG. 22 is a process diagram illustrating steps for processing the components stacked on the lower planarization layer;

FIG. 23 is a sectional view along line B-B according to a first modification of the third embodiment;

FIG. 24 is a sectional view along line B-B according to a second modification of the third embodiment;

FIG. 25 is a sectional view along line A-A according to a fourth embodiment;

FIG. 26 is a diagram for explaining a curve of the outer shape of the bank according to the fourth embodiment;

FIG. 27 is a schematic view of the bank according to a comparative example;

FIG. 28 is an enlarged view of a first part of FIG. 27;

FIG. 29 is an enlarged view of a second part of FIG. 27;

FIG. 30 is a plan view of an example of the structure at and near a cutout according to a comparative example in Dx-Dy plane view;

FIG. 31 is a plan view of an example of the structure at and near the cutout according to a fifth embodiment in Dx-Dy plane view;

FIG. 32 is a plan view of an example of the structure at and near the cutout according to the fifth embodiment in Dx-Dy plane view; and

FIG. 33 is a plan view of an example of the structure at and near the cutout according to the fifth embodiment in Dx-Dy plane view.

### DETAILED DESCRIPTION

Exemplary embodiments according to the present disclosure are described below with reference to the accompanying drawings. What is disclosed herein is given by way of example only, and appropriate modifications made without departing from the spirit of the invention and easily conceivable by those skilled in the art naturally fall within the scope of the present disclosure. To simplify the explanation, the drawings may possibly illustrate the width, the thickness, the shape, and the like of each elements more schematically than the actual aspect. These elements, however, are given by way of example only and are not intended to limit interpretation of the present disclosure. In the present specification and the figures, components similar to those previously described with reference to previous figures are denoted by the same reference numerals, and detailed explanation thereof may be appropriately omitted.

In this disclosure, when an element is described as being “on” another element, the element can be directly on the other element, or there can be one or more elements between the element and the other element.

### First Embodiment

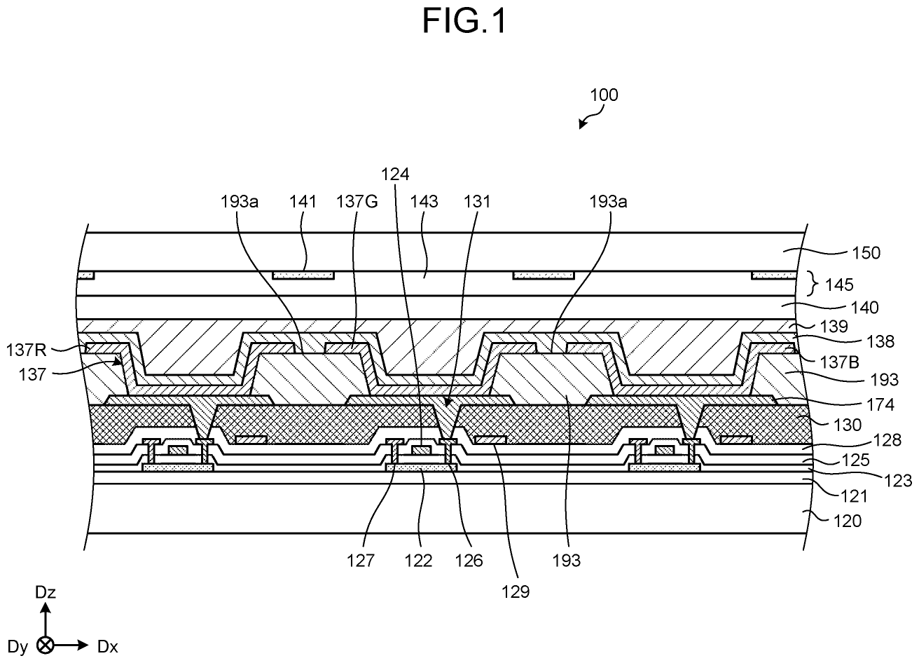

FIG. 1 is a sectional view of an example of a multilayered structure of a display device 100. The display device 100 includes an array substrate 120, a counter substrate 150, and a plurality of components constituting a multilayered structure between the array substrate 120 and the counter substrate 150. In the following description, the counter substrate 150 side with respect to the array substrate 120 is an upper side. In the description of the embodiments, the stacking direction of the array substrate 120 and the counter substrate 150 is a third direction Dz. The direction in which an organic EL layer 137R, an organic EL layer 137G, and an organic EL layer 137B, which will be described later, are arrayed is a first direction Dx. The direction orthogonal to both the third direction Dz and the first direction Dx is a second direction Dy.

A base layer 121, a semiconductor layer including a semiconductor film 122, an interlayer insulating layer 123, a first electrode layer including a gate electrode 124, an interlayer insulating layer 125, a second electrode layer including a drain electrode 126 and a source electrode 127, an interlayer insulating layer 128, a third electrode layer including wiring 129, and a planarization layer 130 are stacked in this order on the array substrate 120.

The base layer 121 and the interlayer insulating layers 123, 125, and 128 are insulating layers containing silicon oxide or silicon nitride, for example. The electrode layers from the first electrode layer to the third electrode layer are particularly required to have low resistance and are each made of a metal layer selected from molybdenum (Mo), titanium (Ti), aluminum (Al), and the like, or a multilayer of these metals. A fourth electrode layer is determined in consideration of a work function for driving organic EL layers 137 and other factors and is made of oxide conductive material selected from indium tin oxide (ITO), indium zinc oxide (IZO), zinc oxide (ZnO), and the like. In a top-emission system, the fourth electrode layer is required to have reflectivity and may have a layer of silver (Ag), Al, or the like as a reflective layer.

On the array substrate 120, a plurality of pixel circuits arrayed in a matrix (row-column configuration) are provided corresponding to pixels 210. Part other than an organic EL element of the pixel circuit is formed in the layers from the base layer 121 to the wiring 129. The semiconductor film 122, the gate electrode 124, the drain electrode 126, and the source electrode 127 constitute a thin-film transistor directly coupled to the organic EL element. The thin-film transistor controls light emission of the pixel 210 corresponding to the pixel circuit including the thin-film transistor. The semiconductor film 122 and the gate electrode 124 overlap in plan view. The region where the semiconductor film 122 and the gate electrode 124 overlap serves as a channel region of the thin-film transistor. The upper surface of the protruding part of the semiconductor film 122 is in contact with the drain electrode 126 and the source electrode 127 passing through the interlayer insulating layers 123 and 125. The planarization layer 130 is an acrylic resin film, for example, and is provided to mainly cover the part other than the organic EL element of the pixel circuit including the thin-film transistor.

The fourth electrode layer including a pixel electrode 174, a bank 193, the organic EL layer 137 including the organic EL layer 137R, the organic EL layer 137G, and the organic EL layer 137B, a common electrode 138, and a sealing film 139 are stacked in this order on the planarization layer 130. As described above, the planarization layer 130 is formed for the substrate (array substrate 120), and the electrodes (pixel electrodes 174) are stacked on the planarization layer 130.

A contact hole 131 is formed on the upper side of the drain electrode 126 in the interlayer insulating layer 128 and the planarization layer 130, and the drain electrode 126 and the pixel electrode 174 are in contact with each other at the bottom of the contact hole 131. Instead of the drain electrode 126, the source electrode 127 may be coupled to the pixel electrode 174 through the contact hole 131.

The organic EL layer 137 is provided on the pixel electrode 174, and the layer of the common electrode 138 made of a transparent electrode, for example, is provided on the organic EL layer 137. The common electrode 138 is covered with the sealing film 139. The pixel electrode 174, the organic EL layer 137, and the common electrode 138 constitute an OLED having the pixel electrode 174 as the anode and the common electrode 138 as the cathode.

The organic EL layer 137 is a light-emitting layer that emits light due to an electric current flowing therethrough by voltage applied by the pixel electrode 174 and the common electrode 138. The organic EL layer 137R, the organic EL layer 137G, and the organic EL layer 137B are made of organic materials having different peak wavelengths of light in light emission. Specifically, the organic EL layer 137R is made of organic material having a peak wavelength of light visually recognized as red (R). The organic EL layer 137G is made of organic material having a peak wavelength of light visually recognized as green (G). The organic EL layer 137B is made of organic material having a peak wavelength of light visually recognized as blue (B). Examples of the organic material include, but are not limited to, phosphorescent material, fluorescent material, etc.

The region where the pixel electrode 174 and the organic EL layer 137 are in contact with each other is positioned directly on the thin-film transistor, or more precisely, directly over the contact hole 131 that couples the drain electrode 126 (or the source electrode 127) to the pixel electrode 174. The organic EL layer 137 emits light in a light-emitting region corresponding to the region where the pixel electrode 174 and the organic EL layer 137 are in contact with each other.

As illustrated in FIG. 1, the section of the bank 193 is what is called a trapezoidal shape with a smaller width toward the upper side. The bank 193 is made of acrylic resin. The lower surface of the bank 193 is in contact with the planarization layer 130 and the pixel electrode 174. The pixel electrode 174 is exposed between the banks 193, and one of the organic EL layer 137R, the organic EL layer 137G, and the organic EL layer 137B is formed on the upper side of the pixel electrode 174.

The organic EL layer 137R, the organic EL layer 137G, and the organic EL layer 137B each extend on the upper side of the bank 193 stacked at both ends of the pixel electrode 174. The bank 193 is interposed between the pixel electrodes 174 arrayed in the first direction Dx and insulates the pixel electrodes 174 adjacently disposed with the bank 193 interposed therebetween.

A filter layer 145 with a black matrix 141 is formed on the surface of the counter substrate 150 facing the array substrate 120. The black matrix 141 is a light-blocking film that blocks light leaking from the boundary of each sub-pixel. A filler 140 is provided between the filter layer 145 and the sealing film 139 stacked on the array substrate 120. The array substrate 120 on which the base layer 121 to the sealing film 139 are stacked and the counter substrate 150 on which the filter layer 145 is formed are bonded together using the filler 140 as an adhesive interposed between the sealing film 139 and the filter layer 145.

In FIG. 1, the organic EL layer 137 may represent colors by color filters provided to the filter layer 145. In this case, the organic EL layer 137R, the organic EL layer 137G, and the organic EL layer 137B are not individually formed, and a light-emitting layer that emits a common color (e.g., white light) is provided in common. In the filter layer 145, color filters in different colors are provided on the upper side of the organic EL layers 137 that are adjacently disposed in the first direction Dx with the black matrix 141 interposed therebetween. The colors of the color filters are red (R), green (G), and blue (B), for example. The colors are not limited thereto and can be appropriately changed.

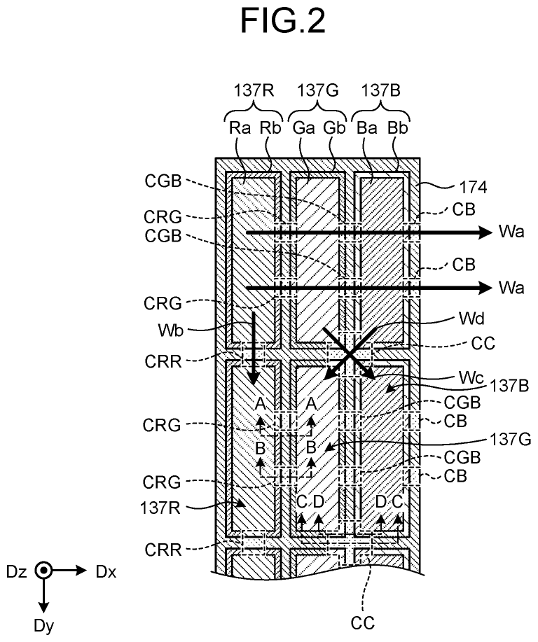

The organic EL layer 137R, the organic EL layer 137G, and the organic EL layer 137B are combined to constitute one pixel. The organic EL layers 137R, 137G, and 137B each function as a sub-pixel. A plurality of sub-pixels, which are not illustrated, are periodically arrayed in the first direction Dx in the order of the organic EL layer 137R, the organic EL layer 137G, and the organic EL layer 137B. As illustrated in FIG. 2, which will be described later, a plurality of sub-pixels of the same color are arrayed in the second direction Dy.

The following describes in particular the multilayered structure of the planarization layer 130, the pixel electrodes 174, the bank 193, and the organic EL layers 137 in the configuration described with reference to FIG. 1 in greater detail with reference to FIGS. 2 to 9.

FIG. 2 is a plan view of an example of the positional relation of the structures of the planarization layer 130, the pixel electrodes 174, the bank 193, and the organic EL layers 137 in Dx-Dy plane view. As illustrated in FIG. 2, the bank 193 separates the organic EL layer 137R, the organic EL layer 137G, and the organic EL layer 137B from one another in a grid pattern. One of the sides of the grid formed by the bank 193 extends along the first direction Dx, and the other extends along the second direction Dy. As described above, the bank 193 protrudes with respect to the electrodes (pixel electrodes 174) in the third direction Dz orthogonal to the first direction Dx and the second direction Dy and surrounds each electrode to form a grid.

The pixel electrodes 174 are disposed in a matrix (row-column configuration) along the first direction Dx and the second direction Dy inside the grid formed by the bank 193. In other words, the pixel electrodes 174 are arrayed in the first direction Dx and the second direction Dy along the plate surface of the array substrate 120. Two pixel electrodes 174 adjacently disposed in the first direction Dx or the second direction Dy are insulated by the bank 193 interposed between the two pixel electrodes 174.

The organic EL layer 137R, the organic EL layer 137G, or the organic EL layer 137B is stacked on the respective pixel electrodes 174 inside the grid formed by the bank 193. The organic EL layer 137R, the organic EL layer 137G, and the organic EL layer 137B are light-emitting layers.

The organic EL layer 137R includes a base portion Ra formed inside the grid formed by the bank 193 and an extending portion Rb extending on the upper side of the bank 193. The organic EL layer 137G includes a base portion Ga formed inside the grid formed by the bank 193 and an extending portion Gb extending on the upper side of the bank 193. The base portion Ga corresponds to a contact region in contact with the pixel electrode 174. The organic EL layer 137B includes a base portion Ba formed inside the grid formed by the bank 193 and an extending portion Bb extending on the upper side of the bank 193.

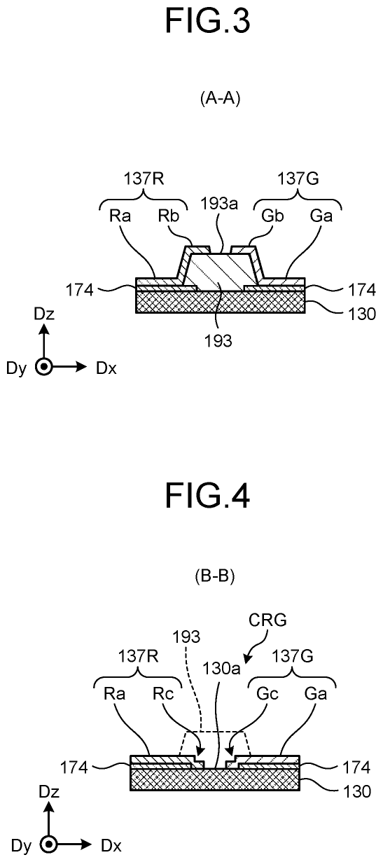

FIG. 3 is a sectional view along line A-A of FIG. 2. The A-A sectional view is a Dx-Dz sectional view illustrating the relation between a first side of the bank 193 the longitudinal direction of which is along the second direction Dy and the organic EL layers 137R and 137G adjacently disposed in the first direction Dx with the first side interposed therebetween.

The Dx-Dz sectional view in FIG. 3 and the subsequent figures do not illustrate the contact hole 131 formed in the planarization layer 130 and schematically illustrate only the positional relation between the planarization layer 130 and the pixel electrode 174.

As illustrated in FIGS. 1 and 3, the shape of the Dx-Dz section of the bank 193 interposed between the organic EL layer 137R and the organic EL layer 137G is an isosceles trapezoid having the bottom side in contact with the planarization layer 130 as the long side and the top side opposite thereto as the short side. As illustrated in FIGS. 1 and 3, the ends of the pixel electrodes 174 in the first direction Dx extend inside the bank 193.

The base portion Ra is in contact with the pixel electrode 174. The extending portion Rb extends from the base portion Ra to the top side of the bank 193 along the wall surface of the isosceles trapezoid of the bank 193. The base portion Ga is in contact with the pixel electrode 174. The extending portion Gb extends from the base portion Ga to the top side of the bank 193 along the wall surface of the isosceles trapezoid of the bank 193. The pixel electrode 174 in contact with the base portion Ra and the pixel electrode 174 in contact with the base Ga are adjacently disposed in the first direction Dx. The bank 193 is interposed between the two pixel electrodes 174 adjacently disposed in the first direction Dx. In other words, the two pixel electrodes 174 adjacently disposed in the first direction Dx are separated from each other with the bank 193 interposed therebetween.

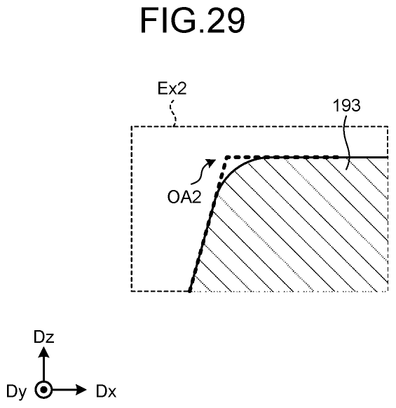

The sectional shape of the bank 193 need not be a precise isosceles trapezoid. For example, the vertices on the short side may be rounded as will be described later with reference to FIG. 29.

The bank 193 has a gap 193a. The gap 193a is positioned on the upper surface of the bank 193 and positioned at and near the center in the first direction Dx of the first side of the bank 193 the longitudinal direction of which is along the second direction Dy. Neither the organic EL layer 137R nor the organic EL layer 137G extends to the gap 193a. In other words, the organic EL layer 137R and the organic EL layer 137G are separated from each other with the gap 193a interposed therebetween.

Although not illustrated in the figure, the relation between the first side of the bank 193 the longitudinal direction of which is along the second direction Dy and the organic EL layers 137G and 137B adjacently disposed in the first direction Dx with the first side interposed therebetween is the same as the positional relation obtained by replacing the organic EL layer 137R illustrated in FIG. 3 with the organic EL layer 137G and replacing the organic EL layer 137G illustrated in FIG. 3 with the organic EL layer 137B except for the part having a cutout, which will be described later. The relation between the first side of the bank 193 the longitudinal direction of which is along the second direction Dy and the organic EL layers 137B and 137R adjacently disposed in the first direction Dx with the first side interposed therebetween is the same as the positional relation obtained by replacing the organic EL layer 137R illustrated in FIG. 3 with the organic EL layer 137B and replacing the organic EL layer 137G illustrated in FIG. 3 with the organic EL layer 137R.

The bank 193 has a cutout in at least part of the grid separating the sub-pixels from one another. The following describes a cutout CRG between the organic EL layer 137R and the organic EL layer 137G illustrated in FIG. 2, for example, with reference to FIG. 4.

FIG. 4 is a sectional view along line B-B of FIG. 2. The B-B sectional view is a Dx-Dz sectional view of the cutout CRG positioned between the organic EL layers 137R and 137G adjacently disposed in the first direction Dx with the first side of the bank 193 the longitudinal direction of which is along the second direction Dy interposed therebetween.

As illustrated in FIG. 4, the bank 193 is not formed between the two pixel electrodes 174 adjacently disposed in the first direction Dx in the cutout CRG. In the cutout CRG, an extending portion Rc extending on the upper side of the pixel electrode 174 is formed to cover the end in the first direction Dx of the pixel electrode 174 in contact with the base portion Ra. In other words, the organic EL layer 137R also includes the extending portion Rc besides the base portion Ra and the extending portion Rb described above.

In the cutout CRG, an extending portion Gc extending on the upper side of the pixel electrode 174 is formed to cover the end in the first direction Dx of the pixel electrode 174 in contact with the base portion Ga. In other words, the organic EL layer 137G also includes the extending portion Gc besides the base portion Ga and the extending portion Gb described above.

The planarization layer 130 has a cutout bottom 130a in the cutout CRG. The cutout bottom 130a is the upper surface of the planarization layer 130 positioned between the extending portions Rc and Gc. Neither the organic EL layer 137R nor the organic EL layer 137G extends to the cutout bottom 130a. In other words, the organic EL layer 137R and the organic EL layer 137G are separated from each other with the cutout bottom 130a interposed therebetween. As described above, the planarization layer 130 is exposed at the bottom of the cutout (e.g., the cutout CRG) of the bank 193.

A cutout CGB (refer to FIG. 2) is positioned between the organic EL layers 137G and 137B adjacently disposed in the first direction Dx with the first side of the bank 193 the longitudinal direction of which is along the second direction Dy interposed therebetween. The Dx-Dz sectional view of the cutout CGB, which is not illustrated, is the same as the sectional view obtained by replacing the organic EL layer 137R illustrated in FIG. 4 with the organic EL layer 137G and replacing the organic EL layer 137G with the organic EL layer 137B. A cutout CB (refer to FIG. 2) is positioned between the organic EL layers 137B and 137R adjacently disposed in the first direction Dx with the first side of the bank 193 the longitudinal direction of which is along the second direction Dy interposed therebetween. The Dx-Dz sectional view of the configuration at and near the cutout CB is the same as the sectional view obtained by replacing the organic EL layer 137R illustrated in FIG. 4 with the organic EL layer 137B and replacing the organic EL layer 137G with the organic EL layer 137R.

The cutout is not limited to the cutout CRG, the cutout CGB, and the cutout CB. For example, a cutout may be formed in the bank 193 that separates the sub-pixels of the same color adjacently disposed in the second direction Dy from one another, like a cutout CRR illustrated in FIG. 2.

The Dy-Dz section of the cutout CRR is the same as the section obtained by replacing the organic EL layer 137G illustrated in FIG. 4 with the organic EL layer 137R and replacing the first direction Dx and the second direction Dy with each other. The Dy-Dz section of the part not having the cutout CRR in the bank 193 extending along the first direction Dx is the same as the section obtained by replacing the organic EL layer 137G illustrated in FIG. 3 with the organic EL layer 137R and replacing the first direction Dx and the second direction Dy with each other.

The cutout may have a shape like a cutout CC illustrated in FIG. 2. The cutout CC is formed at the corner of the grid in plan view. Specifically, the cutout CC illustrated in FIG. 2 is formed at the boundary intersection position where the boundary between the organic EL layer 137G and the organic EL layer 137B adjacently disposed in the first direction Dx intersects the boundary between the two organic EL layers 137G adjacently disposed in the second direction Dy and between the two organic EL layers 137B adjacently disposed in the second direction Dy. In other words, the cutout CC is positioned between the organic EL layer 137G and the organic EL layer 137B adjacently disposed in the first direction Dx with the first side of the bank 193 the longitudinal direction of which is along the second direction Dy interposed therebetween and between the two organic EL layers 137G adjacently disposed in the second direction Dy with a second side of the bank 193 the longitudinal direction of which is along the first direction Dx interposed therebetween and between the two organic EL layers 137B adjacently disposed in the second direction Dy with the second side interposed therebetween.

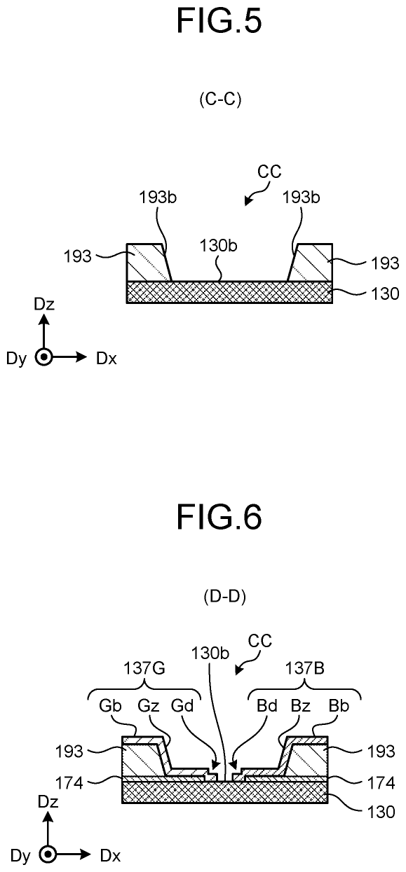

FIG. 5 is a sectional view along line C-C of FIG. 2. The C-C sectional view is a Dx-Dz sectional view of the cutout CC at the position in the second direction Dy overlapping the bank 193 positioned between the two organic EL layers 137G adjacently disposed in the second direction Dy and the two organic EL layers 137B adjacently disposed in the second direction Dy with the second side interposed therebetween.

FIG. 6 is a sectional view along line D-D of FIG. 2. The D-D sectional view is a Dx-Dz sectional view of the cutout CC at the position in the second direction Dy that overlaps the corner of the organic EL layer 137G overlapping the extending portion Gb and overlaps the corner of the organic EL layer 137B overlapping the extending portion Bb.

As illustrated in FIGS. 5 and 6, the cutout CC forms a cutout bottom 130b where neither the bank 193 nor the pixel electrode 174 is stacked on the upper side of the planarization layer 130. As illustrated in FIG. 5, the banks 193 at and near the cutout CC face each other with the cutout CC therebetween. As illustrated in FIG. 5, the cutout CC is formed to be wider from the lower side where the planarization layer 130 is positioned toward the upper side opposite thereto. Therefore, each of the side surfaces of the banks 193 facing each other with the cutout CC therebetween is an inclined surface 193b that makes an obtuse angle with the upper surface of the bank 193 and an acute angle with the lower surface of the bank 193.

At the corner of the organic EL layer 137G overlapping the extending portion Gb in the cutout CC (refer to FIG. 2), the end on the organic EL layer 137B side out of the ends of the pixel electrode 174 in the first direction Dx extends from the bank 193 as illustrated in FIG. 6. The pixel electrode 174 is in contact with the organic EL layer 137G inside the grid formed by the bank 193 (refer to FIG. 1). An extending portion Gd is formed to cover the upper surface and the end in the first direction Dx of the pixel electrode 174. The extending portion Gd is part of the organic EL layer 137G. The extending portion Gd is continuous with the extending portion Gb stacked on the upper side of the bank 193 with a relay portion Gz therebetween. The relay portion Gz is part of the organic EL layer 137G stacked to cover the inclined surface 193b and make the extending portion Gb continuous with the extending portion Gd. In other words, the organic EL layer 137G also includes the relay portion Gz and the extending portion Gd besides the base portion Ga, the extending portion Gb, and the extending portion Gc described above.

At the corner of the organic EL layer 137B overlapping the extending portion Bb in the cutout CC (refer to FIG. 2), the end on the organic EL layer 137G side out of the ends of the pixel electrode 174 in the first direction Dx extends from the bank 193 as illustrated in FIG. 6. The pixel electrode 174 is in contact with the organic EL layer 137B inside the grid formed by the bank 193 (refer to FIG. 1). An extending portion Bd is formed to cover the upper surface and the end in the first direction Dx of the pixel electrode 174. The extending portion Bd is part of the organic EL layer 137B. The extending portion Bd is continuous with the extending portion Bb stacked on the upper side of the bank 193 with a relay portion Bz therebetween. The relay portion Bz is part of the organic EL layer 137B stacked to cover the inclined surface 193b and make the extending portion Bb continuous with the extending portion Bd. In other words, the organic EL layer 137B also includes the relay portion Bz and the extending portion Bd besides the base portion Ba, the extending portion Bb, and the extending portion Bc described above.

The planarization layer 130 has the cutout bottom 130b in the cutout CC. The cutout bottom 130b corresponds to the upper surface of the planarization layer 130. The cutout bottom 130b illustrated in FIG. 6 is positioned between the extending portion Gd and the extending portion Bd adjacently disposed in the first direction Dx. Neither the organic EL layer 137G nor the organic EL layer 137B extends to the cutout bottom 130b. In other words, the organic EL layer 137G and the organic EL layer 137B are separated from each other with the cutout bottom 130b interposed therebetween.

When the cutout CC is not formed, the intersection of the side along the first direction Dx and the side along the second direction Dy of the grid-shaped bank 193 is formed at the boundary intersection position.

A cutout similar to the cutout CC may be formed at the boundary intersection position where the boundary between the organic EL layer 137R and the organic EL layer 137G adjacently disposed in the first direction Dx intersects the boundary between the two organic EL layers 137R adjacently disposed in the second direction Dy and between the two organic EL layers 137G adjacently disposed in the second direction Dy. A cutout similar to the cutout CC may be formed at the boundary intersection position where the boundary between the organic EL layer 137B and the organic EL layer 137R adjacently disposed in the first direction Dx intersects the boundary between the two organic EL layers 137B adjacently disposed in the second direction Dy and between the two organic EL layers 137R adjacently disposed in the second direction Dy.

While FIG. 2 illustrates an example in which no cutout like the cutout CRR between the organic EL layers 137R adjacently disposed in the second direction Dy is formed between the organic EL layers 137G adjacently disposed in the second direction Dy, a cutout similar to the cutout CRR may be formed between the organic EL layers 137G adjacently disposed in the second direction Dy. While FIG. 2 illustrates an example in which no cutout like the cutout CRR between the organic EL layers 137R adjacently disposed in the second direction Dy is formed between the organic EL layers 137B adjacently disposed in the second direction Dy, a cutout similar to the cutout CRR may be formed between the organic EL layers 137B adjacently disposed in the second direction Dy. Both or either of the cutout like the cutout CRR and the cutout like the cutout CC may be formed in the bank 193 surrounding the same sub-pixel.

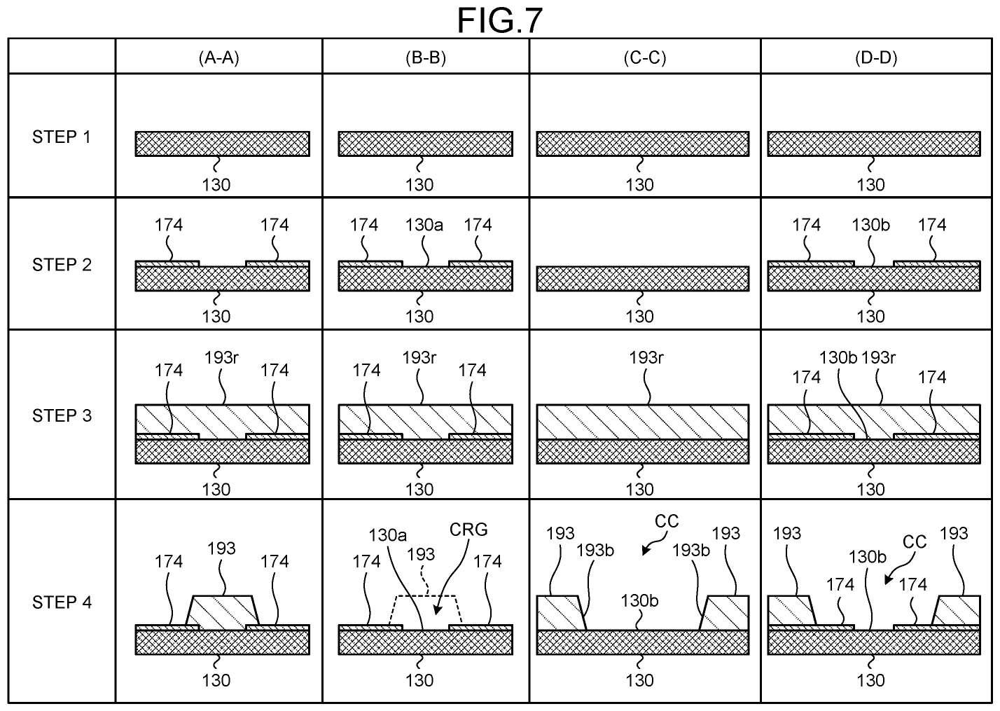

The following describes an example of formation of the multilayered structure including the cutouts, such as the cutout CRG and the cutout CC, with reference to FIGS. 7 to 9. FIGS. 7 to 9 are process diagrams illustrating the steps for processing the components stacked on the planarization layer 130. FIGS. 7 to 9 individually illustrate the A-A section, the B-B section, the C-C section, and the D-D section of FIG. 2. While the directions are not illustrated in FIGS. 7 to 9, the A-A, B-B, C-C, and D-D sections are the Dx-Dz sections as in FIGS. 3 to 6.

Step 1 in FIG. 7 indicates the state where the planarization layer 130 is formed to be stacked on the upper side of the interlayer insulating layer 128 and the wiring 129 described above (refer to FIG. 1). Step 2 in FIG. 7 indicates the state where the pixel electrodes 174 are formed to be stacked on the upper side of the planarization layer 130 formed at Step 1. As illustrated in the A-A, B-B and D-D sections at Step 2, the pixel electrodes 174 provided to the respective two sub-pixels adjacently disposed in the first direction Dx are formed to be separated from each other. In the B-B section, the two pixel electrodes 174 are adjacently disposed and separated from each other in the first direction Dx with the cutout bottom 130a interposed therebetween. The pixel electrodes 174 are not formed at the position of the C-C section.

Photolithography, for example, is employed in the process for forming the layers, including the pixel electrodes 174, stacked in the display device 100. There are two methods for photolithography: a subtractive method and an additive method. The subtractive method is as follows: a multilayered structure to be formed is formed on the entire panel and is then coated with parylene and photoresist, and a development process is performed to remove unnecessary portions, thereby causing the structure to be formed to remain on the panel. The additive method is as follows: coating with parylene and photoresist is performed first, a development process is performed to form a mask pattern corresponding to the structure to be formed, a multilayered structure to be formed is then formed on the panel, and the unnecessary mask is removed. The embodiment may employ the subtractive method or the additive method.

Some of the steps for forming the layers stacked in the display device 100 are not limited to photolithography and may be performed by other methods, such as metal mask. At least some of the steps for manufacturing the display device 100 are performed by photolithography.

Step 3 in FIG. 7 indicates the state where a bank layer 193r to be formed into the bank 193 is formed on the upper side of the pixel electrodes 174 formed at Step 2. As illustrated in Step 3, the bank layer 193r entirely covers the top of the pixel electrodes 174 and the top of the planarization layer 130 the upper surface of which is exposed between the pixel electrodes 174. As a result, the cutout bottom 130a in the B-B section exposed at Step 2 is covered with the bank layer 193r at Step 3.

The bank layer 193r is a layer made of polymeric material, such as polyimide and acrylic. In other words, the bank 193 or the like formed by shaping the bank layer 193r is also made of such polymeric material.

Step 4 in FIG. 7 indicates the state where the bank layer 193r formed at Step 3 is shaped to form the grid-shaped bank 193 (refer to FIG. 2) and the cutout. As a result, the isosceles trapezoidal bank 193 is formed so as to separate the two pixel electrodes 174 adjacently disposed in the first direction Dx on the planarization layer 130 at a position where no cutout is formed as illustrated in the A-A section at Step 4. By forming the cutout CRG at Step 4, the cutout bottom 130a in the B-B section covered with the bank layer 193r at Step 3 is exposed at Step 4. By forming the cutout CC at Step 4, the inclined surfaces 193b and the cutout bottom 130b are formed as illustrated in the C-C section. By forming the cutout CC at Step 4, the ends of the two pixel electrodes 174 disposed and separated from each other with the cutout bottom 130b interposed therebetween are exposed in the cutout CC as illustrated in the D-D section.

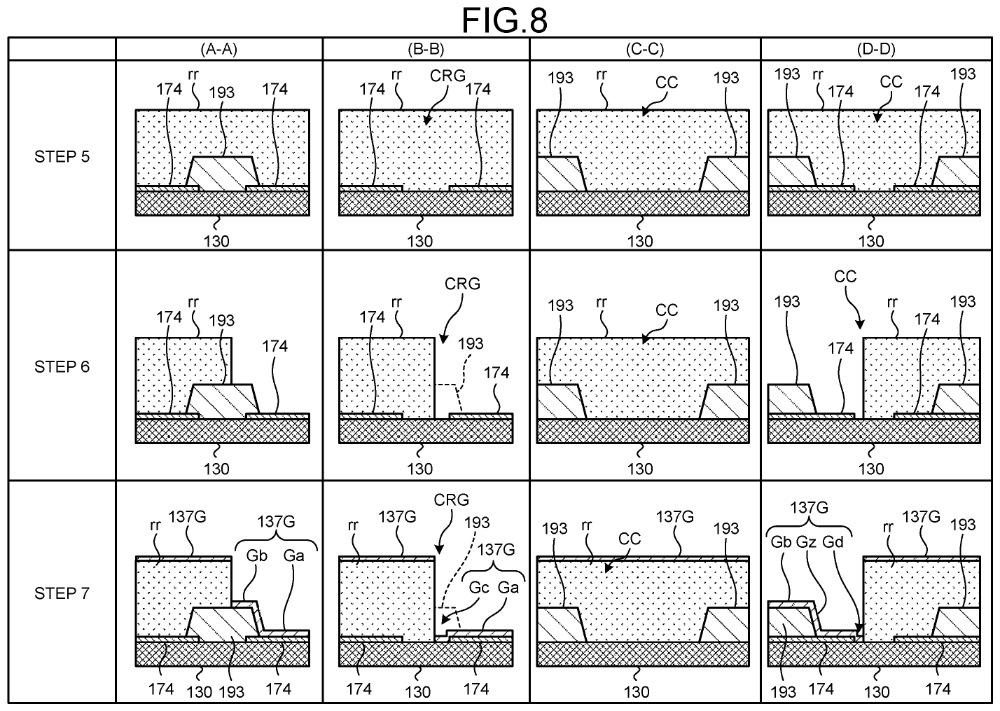

Step 5 at FIG. 8 indicates the state where a resist layer rr is formed on the upper side of the bank 193 formed at Step 4 in FIG. 7. The resist layer rr has a multilayered structure with a parylene layer at the bottom and a photoresist layer at the top, for example. The cutout CRG in the B-B section and the cutout CC in the C-C and D-D sections exposed at Step 4 are covered with the resist layer rr at Step 5. The resist layer rr may have a single-layered or multilayered structure of novolac resin, phenolic resin, fluorinated polymer, and the like.

Step 6 in FIG. 8 indicates the state where the area where the organic EL layer 137G is to be formed is removed from the resist layer rr formed at Step 5. When the photoresist included in the resist layer rr is positive photoresist, the area where the organic EL layer 137G is to be formed is exposed in the development process in photolithography, and the exposed photosensitive part is removed by being immersed in a developer. In the following description, when simply referring to “development process”, it means the development process in photolithography. When the photoresist included in the resist layer rr is negative photoresist, the area where the organic EL layer 137G is not to be formed is exposed in the development process, and the non-exposed non-photosensitive part is removed by being immersed in a developer.

Step 7 in FIG. 8 indicates the state where the organic EL layer 137G is stacked and formed on the layered body obtained by forming the resist layer rr at Step 5 and removing the area where the organic EL layer 137G is to be formed from the resist layer rr at Step 6. Thus, the base portion Ga and the extending portion Gb are formed in the region viewed in the A-A section. The base portion Ga and the extending portion Gc are formed in the region viewed in the B-B section. The extending portion Gb, the relay portion Gz, and the extending portion Gd are formed in the region viewed in the D-D section. At Step 7, the organic EL layer 137G is also stacked on the upper side of the resist layer rr not removed.

FIG. 8 illustrates in particular an example of the process for forming the organic EL layer 137G in the process for stacking the components on the planarization layer 130. While FIG. 8 illustrates the case where the additive method of photolithography is employed, the subtractive method may be employed.

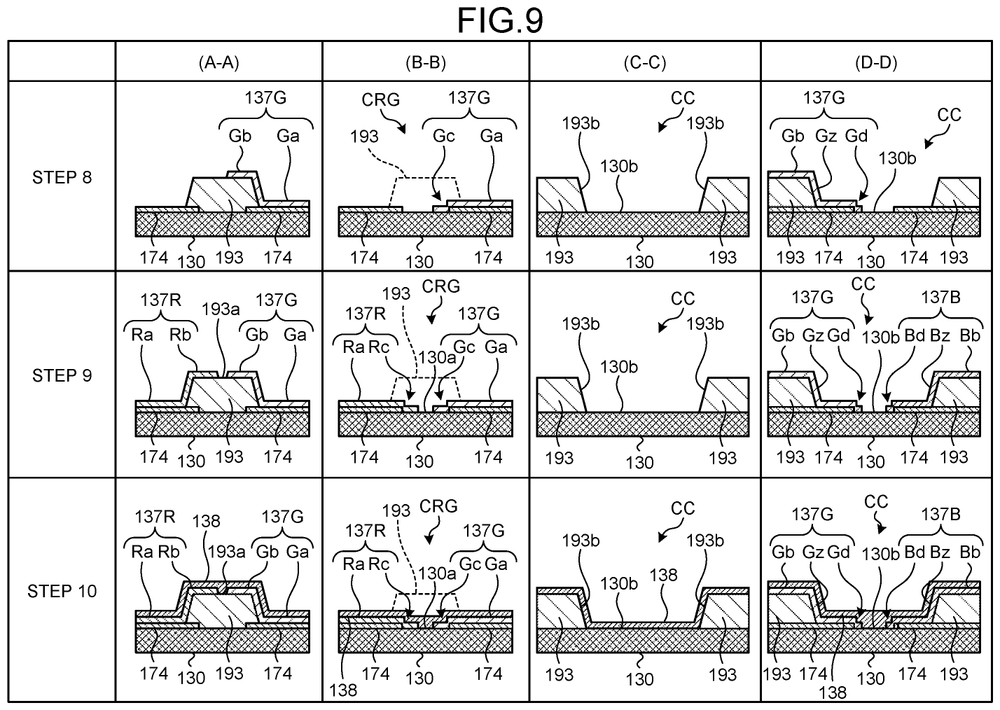

Step 8 in FIG. 9 indicates the state where the resist layer rr not removed in FIG. 7 is removed. Specifically, in a stripping process in photolithography, the layered body subjected to the steps from Step 1 to Step 7 is immersed in a stripper, and the unnecessary resist layer rr with the organic EL layer 137G stacked thereon is removed.

When the positive photoresist is employed, organic alkaline solutions not containing metal ions, such as tetramethylammonium hydroxide solution and fluorinated liquid like hydrofluoroether, are mainly used as the developer. When the negative photoresist is employed, organic solvents are mainly used as the developer. The developer is not limited to those described above, and any liquid that enables the development process can be appropriately used. Organic alkali solutions, aqueous solutions, and fluorinated liquids, such as hydrofluoroether, are mainly used as the stripper. The stripper is not limited to those described above, and any liquid that enables the stripping process can be appropriately used. To wash away the developer used in the development process, the layered body is washed using a cleaning solution. The cleaning solution is pure water or dedicated rinse solution for the developer, for example. To wash away the stripper used in the stripping process, the layered body is washed using a cleaning solution. The cleaning solution is pure water or dedicated rinse solution for the stripper, for example.

While neither the organic EL layer 137R nor the organic EL layer 137B is formed at Steps 5, 6, and 7 in FIG. 8 and Step 8 in FIG. 9, at least one of the organic EL layer 137R and the organic EL layer 137B may be formed before the formation of the organic EL layer 137G. The method for forming the organic EL layer 137R and the organic EL layer 137B may be the additive method like the method for forming the organic EL layer 137G described with reference to Steps 5, 6, and 7 in FIG. 8 and Step 8 in FIG. 9 or the subtractive method.

Step 9 in FIG. 9 indicates the state where the organic EL layer 137R, the organic EL layer 137G, and the organic EL layer 137B are formed on the upper side of the layered body illustrated in Step 4 in FIG. 7. By advancing the process to this state, the structures of the planarization layer 130, the pixel electrodes 174, the bank 193, and the organic EL layers 137 described with reference to FIGS. 2 to 6 are formed.

Step 10 in FIG. 9 indicates the state where the common electrode 138 is stacked and formed on the upper side of the layered body formed by Step 9. As a result, the organic EL layer 137R, the organic EL layer 137G, and the gap 193a in the A-A section are covered with the common electrode 138. The organic EL layer 137R, the organic EL layer 137G, and the cutout bottom 130a in the B-B section are covered with the common electrode 138. The bank 193 and the cutout bottom 130b in the C-C section are covered with the common electrode 138. The organic EL layer 137G, the organic EL layer 137B, and the cutout bottom 130b in the D-D section are covered with the common electrode 138.

In a process after Step 10 (not illustrated), the sealing film 139 is formed on the top (refer to FIG. 1). The array substrate 120 on which stacking of the sealing film 139 is completed is bonded to the counter substrate 150 provided with the filter layer 145 on the bottom with the filler 140 interposed therebetween.

In photolithography, the layered body constituting the display device 100 is exposed to the developer and the stripper during the manufacturing process as described above. If the cleaning solution remains on the layered body after the washing of the layered body performed after the development process and the stripping process, the residue contains the components of the developer or the stripper. If the developer or the stripper remains on the layered body for a long time, it may possibly damage the layered body. For this reason, it is preferable that the layered body be washed immediately after the development process and the stripping process and that a removal process be performed to remove the cleaning solution remaining after washing from the layered body. In the following description, when simply referring to “removal process”, it means the removal process described above. In the removal process, an air knife is used, for example.

The air knife is a blower (blowing machine) that emits compressed air from a plurality of nozzles arranged in a row to create a continuous airflow layer (air curtain) in the direction of the row of the nozzles. When the air knife is used, the air curtain is blown on the layered body, whereby the cleaning solution remaining after washing is blown away and removed from the layered body.

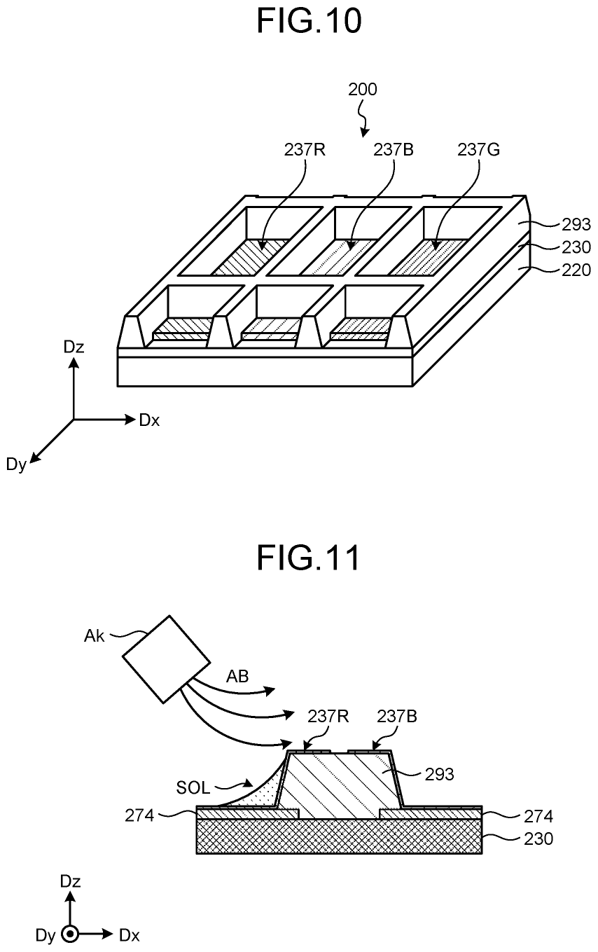

The use of an air knife or a spin dryer, however, may possibly fail to sufficiently remove the developer, the stripper, and the cleaning solution remaining after washing depending on the multilayered structure of the display device. The following describes a display device 200 as a reference example with reference to FIGS. 10 and 11.

FIG. 10 is a perspective view of a bank structure of the display device 200 according to the reference example. As illustrated in FIG. 10, a bank 293 of the display device 200 has a grid shape that separates an organic EL layer 237R, an organic EL layer 237G, and an organic EL layer 237B from one another. None of the cutouts CRG, CGB, CB, CRR and CC described above are formed in the bank 293. The bank 293 is the same as the bank 193 described above except that it has no cutout. The organic EL layer 237R is an organic EL layer having only the base portion Ra or the base portion Ra and the extending portion Rb of the organic EL layer 137R described above. The organic EL layer 237G is an organic EL layer having only the base portion Ga or the base portion Ga and the extending portion Gb of the organic EL layer 137G described above. The organic EL layer 237B is an organic EL layer having only the base portion Ba or the base portion Ba and the extending portion Bb of the organic EL layer 137B described above. A planarization layer 230 with the bank 293 stacked thereon is the same as the planarization layer 130 described above. An array substrate 220 with the planarization layer 230 stacked thereon is the same as the array substrate 120 described above.

FIG. 11 is a schematic view illustrating how the bank 293 prevents removal of a solution SOL. In FIG. 11, airflow AB generated by an air knife Ak is supplied when the solution SOL remains on the organic EL layer 237R inside the grid of the bank 293. The direction from the upstream to the downstream of the airflow AB illustrated in FIG. 11 includes the component of the first direction Dx. The airflow AB applies, to the solution SOL, a biasing force of moving in the first direction Dx. However, the bank 293 positioned in the first direction Dx with respect to the solution SOL blocks the solution SOL, thereby preventing removal of the solution SOL.

While FIG. 11 illustrates the solution SOL on the organic EL layer 237R, for example, the same situation occurs on the organic EL layer 237G and the organic EL layer 237B.

By contrast, the bank 193 according to the first embodiment has the cutout CRG. If the solution SOL is present on the bank 193, the residue subjected to the biasing force, which is represented as the arrows Wa (refer to FIG. 2), of moving in the first direction Dx by the airflow AB is discharged and removed through the cutout CRG to the organic EL layer 137G. Similarly, if the solution SOL is present on the organic EL layer 137G, it is discharged and removed through the cutout CGB to the organic EL layer 137G. Similarly, if the solution SOL is present on the organic EL layer 137B, it is discharged and removed through the cutout CB to the outside, which is not illustrated. In other words, as illustrated in FIG. 2, the configuration of the first embodiment includes a first pixel, a second pixel, and a third pixel adjacently disposed in the first direction Dx. A first cutout (cutout CRG) in the bank 193 between the first pixel and the second pixel and a second cutout (cutout CGB) in the bank 193 between the second pixel and the third pixel are arranged in a line. In the example illustrated in FIG. 2, the first pixel is a sub-pixel provided with the organic EL layer 137R. The second pixel is a sub-pixel provided with the organic EL layer 137G. The third pixel is a sub-pixel provided with the organic EL layer 137B.

The direction of the biasing force applied to the solution SOL according to the first embodiment when the solution SOL is present is not limited to that indicated by the arrow Wa. For example, by forming the cutout CRR, it is possible to handle the case where a biasing force, which is represented as the arrow Wb (refer to FIG. 2) along the second direction Dy, is applied to the solution SOL. In other words, as illustrated in FIG. 2, the configuration of the first embodiment includes the first pixel, a fourth pixel, and a fifth pixel adjacently disposed in the second direction Dy. A third cutout (cutout CRR) in the bank between the first pixel and the fourth pixel and a fourth cutout (cutout CRR) in the bank between the fourth pixel and the fifth pixel are arranged in a line. In the example illustrated in FIG. 2, each of the first, the fourth, and the fifth pixels is a sub-pixel provided with the organic EL layer 137R, and the first, the fourth, and the fifth pixels are adjacently disposed in this order from one end to the other in the second direction Dy.

By forming the cutout CC, it is possible to handle the case where a biasing force, which is represented as the arrow We (refer to FIG. 2) or the arrow Wd (refer to FIG. 2) intersecting the first direction Dx and the second direction Dy, is applied to the solution SOL. Therefore, if a solution (e.g., cleaning solution remaining after washing) that can be a residue if left unattended, such as the solution SOL, is present, the first embodiment can satisfactorily remove it through the cutouts by the biasing force applied in the removal process. Thus, the solution can be more satisfactorily removed by forming the cutouts corresponding to the direction of the airflow generated by the air knife. Out of the various cutouts, such as the cutouts CRG, CGB, CB, CRR, and CC in the description above, some cutouts not corresponding to the direction of the airflow generated by the air knife may be omitted. Another cutout, which is not formed in the example illustrated in FIG. 2, may be formed in a second side of the bank 193 facing a first side having the cutout CRG with the organic EL layer 137R therebetween. In this case, the position of the cutout in the second direction Dy is preferably the same as that of the cutout CRG. As described above, the cutouts are formed along the biasing force applied to a liquid used in the stacking process of at least one or more of the pixel electrodes 174, the bank 193, and the light-emitting layer (e.g., the organic EL layer 137R, the organic EL layer 137G, or the organic EL layer 137B) by an external machine that removes the liquid.

The component that applies the biasing force to the solution that can be a residue if left unattended is not limited to the air knife Ak for generating an airflow, such as the airflow AB. For example, a spin dryer may be used instead of the air knife Ak. The spin dryer rotates the array substrate 120 on which the layered body has been formed around a rotation axis along the third direction Dz. When the spin dryer is used, the rotational force generated by the spin dryer exerts centrifugal force on the solution on the layered body, whereby the solution is blown away and removed from the layered body. In the display device 200, however, removal of the solution SOL is prevented by the bank 293 blocking the solution SOL in the same manner as the case where the biasing force is applied by the airflow AB.

To use the spin dryer in the first embodiment, a plurality of cutouts are preferably formed in the bank 193 in such a positional relation that they form flow paths extending outward along the radial direction around the rotation axis of the spin dryer with respect to the rotation axis. With this configuration, if a solution that can be a residue if left unattended is present on the layered body, the solution subjected to the biasing force by the centrifugal force can pass through the cutouts and be satisfactorily blown away outward and removed.

The cutout preferably has such a size that allows the residual solution remaining after washing to satisfactorily flow therethrough. When the size of one grid formed by the bank 193 is Dx×Dy=24 μt×72 μm, for example, the width of the cutout CRG in the second direction Dy is 10 μm. The size of the cutout CC is Dx×Dy=5 μm×5 μm.

As described above, the display device 100 according to the first embodiment includes the substrate (array substrate 120), the planarization layer 130, the electrodes (pixel electrodes 174), the bank 193, and the light-emitting layers (the organic EL layer 137R, the organic EL layer 137G, and the organic EL layer 137B). The planarization layer 130 is provided on the substrate. The electrodes are provided on the planarization layer 130 and arrayed in the first direction Dx and the second direction Dy. The bank 193 is provided on the planarization layer 130 and the electrodes and surrounds each of the electrodes to be formed in a grid pattern. The light-emitting layers are provided on the electrodes. The bank 193 protrudes with respect to the electrodes in the third direction Dz orthogonal to the first direction Dx and the second direction Dy, and the cutout (e.g., the cutouts CRG, CGB, CB, CRR, and CC) is formed in part of the bank 193. With this configuration, the residual solution remaining after washing can pass through the cutout. Therefore, the residual solution remaining after washing can be more readily removed.

The planarization layer 130 is exposed at the bottom of the cutout (e.g., the cutouts CRG, CGB, CB, CRR, and CC) in the bank 193. This configuration can prevent the structure of the bank 193 from extending upward at the position of the cutout, thereby allowing the residual solution remaining after washing to more readily pass through the cutout.

The method for manufacturing an organic electroluminescent display panel according to the embodiment is a method for manufacturing an organic electroluminescent display panel including the planarization layer 130 formed on the substrate (array substrate 120), the electrodes (pixel electrodes 174) formed on the planarization layer 130, the bank 193 formed on the planarization layer 130 and each of the electrodes and formed in a grid pattern so as to surround each of the electrodes, and the organic EL layers (the organic EL layer 137R, the organic EL layer 137G, and the organic EL layer 137B) formed on the electrodes. The manufacturing method includes patterning by photolithography such that the cutout (e.g., the cutouts CRG, CGB, CB, CRR, and CC) is formed in part of the bank 193 in a display region in which the electrodes are formed, removing the resist layer rr in the area where the organic EL layer is to be formed by immersing it in a solution, and removing the solution from the organic electroluminescent display panel. At the removing the solution, compressed air is emitted so as to blow away the solution. The cutout is formed along the direction of emission of the compressed air. With this configuration, the solution blown away by emission of the compressed air can pass through the cutout. Therefore, the residual solution remaining after washing can be more readily removed.

The electrodes (pixel electrodes 174) are arrayed in the first direction Dx and the second direction Dy. By forming a plurality of cutouts (e.g., the cutouts CRG, CGB, CB, and CRR) along the first direction Dx or the second direction Dy and setting the direction of emission of the compressed air to the direction of the cutouts, the solution can be more readily removed.

By forming the cutouts (cutouts CC) at the corners of the grid of the bank 193 formed in a grid pattern so as to surround each of the electrodes and setting the direction of emission of the compressed air to the direction of the cutouts formed along the diagonals, the solution can be more readily removed.

### Second Embodiment

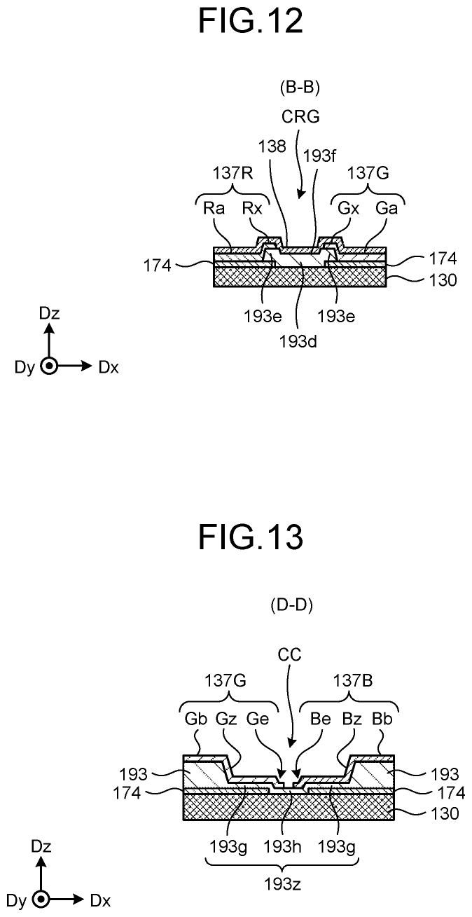

The following describes a second embodiment partially different from the first embodiment with reference to FIGS. 12 to 16. In the description of the second embodiment, the same components as those according to the first embodiment are denoted by the same reference numerals, and explanation thereof may be omitted.

FIG. 12 is a sectional view along line B-B according to the second embodiment. As illustrated in FIG. 12, the cutout CRG according to the second embodiment has a cutout bottom 193d. The cutout bottom 193d is interposed between the two pixel electrodes 174 facing each other in the first direction Dx with the cutout CRG therebetween.

The cutout bottom 193d includes covering portions 193e and a covering portion 193f. The covering portions 193e are positioned at both ends of the cutout bottom 193d in the first direction Dx and cover the ends of the two pixel electrodes 174 facing each other in the first direction Dx with the cutout CRG therebetween. The covering portion 193f is positioned between the two covering portions 193e. The covering portion 193f is positioned lower in the third direction Dz than the covering portions 193e and forms a recessed shape with the covering portions 193e serving as the edges.

The cutout bottom 193d is provided not by removing the entire bank layer 193r in the cutout CRG at the position of the B-B section when proceeding from Step 3 to Step 4 described above but by shaping the bank layer 193r so as to form the cutout bottom 193d having a shape corresponding to the covering portions 193e and the covering portion 193f. Specifically, the cutout bottom 193d is formed by using halftone corresponding to the cutout bottom 193d in photolithography, for example.

According to the second embodiment, with the cutout bottom 193d having the covering portions 193e, an end Rx of the organic EL layer 137R on the cutout CRG side is formed to extend onto one of the two covering portions 193e. Therefore, the organic EL layer 137R according to the second embodiment has the end Rx instead of the extending portion Rc described above. According to the second embodiment, an end Gx of the organic EL layer 137G on the cutout CRG side is formed to extend onto one of the two covering portions 193e. Therefore, the organic EL layer 137G according to the second embodiment has the end Gx instead of the extending portion Gc described above.

Before explaining the advantageous effects of the cutout bottom 193d, the following describes the cutout CRG according to the first embodiment. As illustrated in Step 10 described above, the common electrode 138 is stacked on the upper side of the organic EL layers 137R and 137G in the cutout CRG. The pixel electrodes 174 are stacked on the lower side of the organic EL layers 137R and 137G in the cutout CRG. In the configuration according to the first embodiment, the extending portions Rc and Gc have a step shape corresponding to the step between the pixel electrode 174 and the planarization layer 130 in the cutout CRG. The wall surface of the step along the third direction Dz may possibly be thinner. In this case, the electrical resistance of the organic EL layers 137R and 137G between the common electrode 138 and the pixel electrode 174 may possibly fail to be sufficiently secured. If the electrical resistance of the organic EL layers 137R and 137G is insufficient, a short circuit may possibly occur between the common electrode 138 and the pixel electrode 174.

To address this, the configuration of the second embodiment has the cutout bottom 193d, thereby more reliably securing the electrical resistance between the organic EL layers 137R and 137G and the pixel electrodes 174. Therefore, a short circuit between the common electrode 138 and the pixel electrode 174 can be less likely to occur.

FIG. 13 is a sectional view along line D-D according to the second embodiment. As illustrated in FIG. 13, the cutout CC according to the second embodiment has a cutout bottom 193z. The cutout bottom 193z has covering portions 193g and a covering portion 193h. The covering portions 193g cover the upper surface of the two pixel electrodes 174 exposed in the cutout CC according to the first embodiment. The covering portion 193h is interposed between the two pixel electrodes 174 facing each other in the first direction Dx with the cutout CC therebetween. The covering portion 193h is continuous with the covering portions 193g at both ends in the first direction Dx. Therefore, the ends of the two pixel electrodes 174 in the cutout CC are covered with the covering portions 193g and the covering portion 193h.

The covering portions 193g and the covering portion 193h are provided not by removing the entire bank layer 193r in the cutout CC at the position of the D-D section when proceeding from Step 3 to Step 4 described above but by shaping the bank layer 193r so as to form a shape corresponding to the covering portions 193g and the covering portion 193h. Specifically, the covering portions 193g and the covering portion 193h are provided by using halftone corresponding to the covering portions 193g and the covering portion 193h in photolithography, for example.

According to the second embodiment, an end Ge of the organic EL layer 137G on the cutout CC side is stacked on a part of the upper surface of the covering portion 193h and one of the covering portions 193g. Thus, the organic EL layer 137G according to the second embodiment has the end Ge instead of the extending portion Gd described above. The covering portion 193h and one of the covering portions 193g are interposed between the end Ge of the organic EL layer 137G on the cutout CC side and the pixel electrode 174.

An end Be of the organic EL layer 137B on the cutout CC side according to the second embodiment is stacked on another part of the upper surface of the covering portion 193h and the other of the covering portions 193g. Thus, the organic EL layer 137B according to the second embodiment has the end Be instead of the extending portion Bd described above. The covering portion 193h and the other of the covering portions 193g are interposed between the end Be of the organic EL layer 137G on the cutout CC side and the pixel electrode 174.

The end Ge and the end Be extending to the upper surface of the covering portion 193h are separated and face each other in the first direction Dx.

Before explaining the advantageous effects of the cutout bottom 193z, the following describes the cutout CC according to the first embodiment. As illustrated in Step 10 described above, the common electrode 138 is stacked on the upper side of the organic EL layers 137G and 137B in the cutout CC. The pixel electrodes 174 are stacked on the lower side of the organic EL layers 137G and 137B in the cutout CC. In the configuration according to the first embodiment, the extending portions Gd and Bd have a step shape corresponding to the step between the pixel electrode 174 and the planarization layer 130 in the cutout CC. The thickness of the wall surface of the step along the third direction Dz may possibly be thinner. In this case, the electrical resistance of the organic EL layers 137G and 137B between the common electrode 138 and the pixel electrode 174 may possibly fail to be sufficiently secured. If the electrical resistance of the organic EL layers 137G and 137B is insufficient, a short circuit may possibly occur between the common electrode 138 and the pixel electrode 174.

To address this, the configuration of the second embodiment has the cutout bottom 193z, thereby more reliably securing the electrical resistance between the organic EL layers 137G and 137B and the pixel electrodes 174. Therefore, a short circuit between the common electrode 138 and the pixel electrode 174 can be less likely to occur.

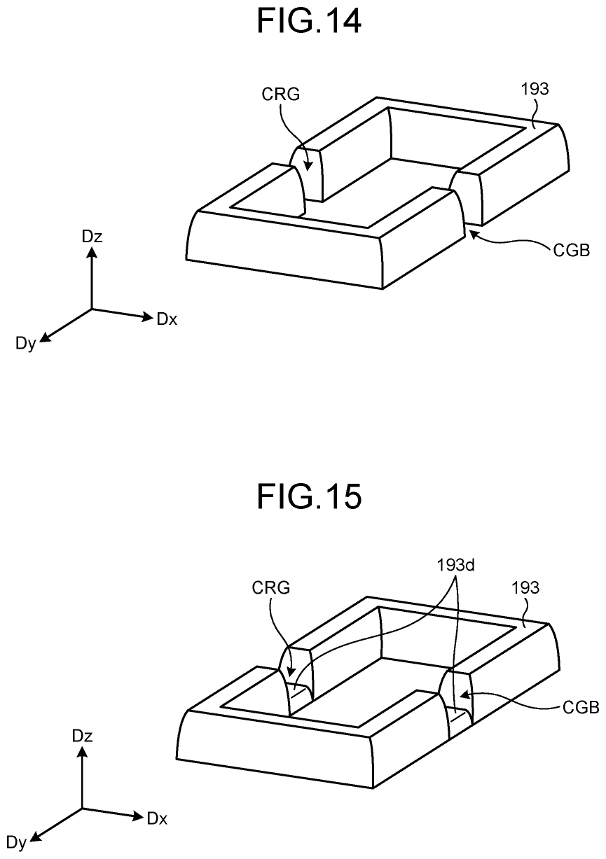

The following describes an example where one cutout is formed in each bank 193 extending along the second direction Dy according to the first embodiment and the second embodiment with reference to the schematic views in FIGS. 14 to 16 to compare the first embodiment, the second embodiment, and the reference example (refer to FIGS. 10 and 11).

FIG. 14 is a schematic view of the shape of the bank 193 according to the first embodiment. As illustrated in FIG. 14, the cutout, such as the cutouts CRG and CGB, according to the first embodiment is formed to completely break the continuity of the bank 193 in the second direction Dy at the position of the cutout.

FIG. 15 is a schematic view of the shape of the bank 193 according to the second embodiment. As illustrated in FIG. 15, the cutout, such as the cutouts CRG and CGB, according to the second embodiment is formed such that the cutout bottom 193d is provided at the position of the cutout. Thus, the cutout bottom 193d of the cutout (e.g., the cutouts CRG and CGB) according to the second embodiment is made of a polymeric material layer obtained by shaping the bank layer 193r. The cutout bottom 193d is stacked on the planarization layer 130 and the pixel electrodes 174 and covers the ends of the pixel electrodes 174. The bank layer 193r serving as the polymeric material layer includes the bank 193 and the cutout bottom 193d after shaping.

The thickness of the bank 193 from the planarization layer 130 to the bottom (cutout bottom 193d) of the cutout (e.g., the cutouts CRG and CGB) is less than the thickness from the planarization layer 130 to the upper surface (gap 193a) of the bank 193. Specifically, the height of the cutout bottom 193d and the cutout bottom 193z in the third direction Dz is preferably less than half the height of the bank 193 in the third direction Dz.

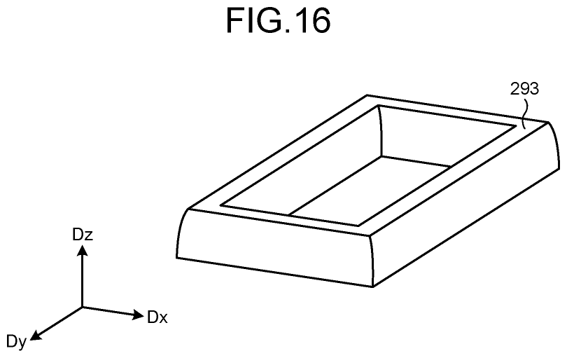

FIG. 16 is a schematic view of the shape of the bank 293 according to the reference example. As illustrated in FIG. 16, the bank 293 according to the reference example does not have a shape corresponding to the cutout according to the first embodiment and the second embodiment.

The Dx-Dz sectional view of the cutout CGB (refer to FIG. 2) according to the second embodiment is the same as the sectional view obtained by replacing the organic EL layer 137R illustrated in FIG. 12 with the organic EL layer 137G and replacing the organic EL layer 137G with the organic EL layer 137B. The Dx-Dz sectional view of the configuration at and near the cutout CB (refer to FIG. 2) according to the second embodiment is the same as the sectional view obtained by replacing the organic EL layer 137R illustrated in FIG. 12 with the organic EL layer 137B and replacing the organic EL layer 137G with the organic EL layer 137R. The Dy-Dz section of the cutout CRR (refer to FIG. 2) according to the second embodiment is the same as the section obtained by replacing the organic EL layer 137G illustrated in FIG. 12 with the organic EL layer 137R and replacing the first direction Dx and the second direction Dy with each other. Except for the items noted above, the second embodiment is the same as the first embodiment.

The thickness of the bank 193 according to the second embodiment from the planarization layer 130 to the upper surface of the bank 193 in the cutout (e.g., the cutouts CRG, CGB, CB, CRR, and CC) is less than the thickness of the bank from the planarization layer 130 to the upper surface (gap 193a) of the bank 193 at the position where the cutout is not formed. This configuration enables both reducing occurrence of a short circuit between the pixel electrode 174 and the common electrode 138 and readily removing the residual solution remaining after washing.

The polymeric material layer formed by shaping the bank layer 193r includes the bank 193, the cutout bottom 193d, and the cutout bottom 193z. Therefore, the cutout bottom 193d and the cutout bottom 193z can be formed simultaneously with the formation of the bank 193.

### Third Embodiment

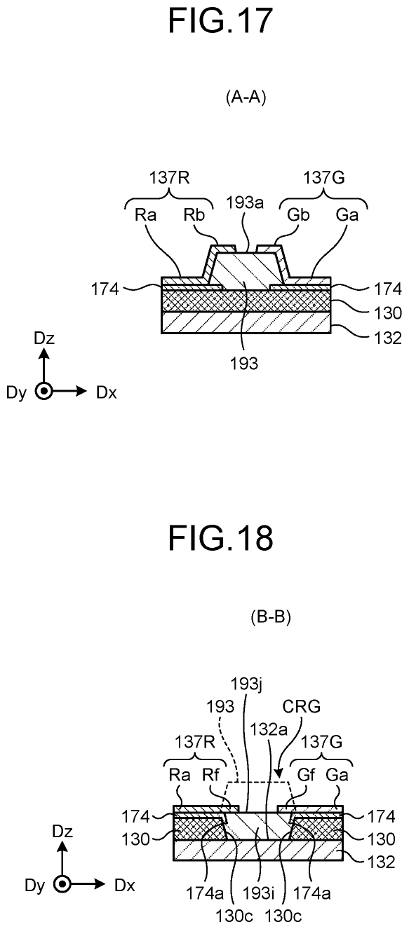

The following describes a third embodiment partially different from the first embodiment with reference to FIGS. 17 to 22. In the description of the third embodiment, the same components as those according to the first embodiment are denoted by the same reference numerals, and explanation thereof may be omitted.

FIG. 17 is a sectional view along line A-A according to the third embodiment. As illustrated in FIG. 17, the multilayered structure on the lower side of the pixel electrodes 174 according to the third embodiment is a two-layer structure composed of the planarization layer 130 and a planarization layer 132. In other words, in the third embodiment, the one-layer structure of the planarization layer 130 stacked on the interlayer insulating layer 128 (refer to FIG. 1) and the wiring 129 (refer to FIG. 1) according to the first embodiment is replaced by the two-layer structure of the planarization layer 130 and the planarization layer 132. The planarization layer 132 is positioned on the lower side of the planarization layer 130. As described above, in the third embodiment, a second planarization layer (planarization layer 130) is stacked on the upper side of a first planarization layer (planarization layer 132). In the third embodiment, the electrodes (pixel electrodes 174) are stacked on the upper side of the second planarization layer (planarization layer 130).

FIG. 18 is a sectional view along line B-B according to the third embodiment. The planarization layer 130 according to the third embodiment is shaped to be cut out downward at the position of the cutout CRG. The side surface of the planarization layer 130 shaped in this manner is an inclined surface 130c that makes an obtuse angle with the upper surface of the planarization layer 130 and an acute angle with the lower surface of the planarization layer 130. In the example illustrated in FIG. 18, the planarization layer 130 is shaped to form a hole bottom 132a where the planarization layer 130 covering the upper surface of the planarization layer 132 is not stacked in the cutout CRG.

In the third embodiment, ends 174a of the two pixel electrodes 174 facing each other in the first direction Dx with the cutout CRG therebetween are each formed to incline downward along the inclined surface 130c. As described above, the end (end 174a) of the electrode (pixel electrode 174) according to the third embodiment partially covers the edge of the hole (hole H) in the second planarization layer (planarization layer 130). In the example illustrated in FIG. 18, the lower end of the end 174a does not reach the hole bottom 132a.

A filling portion 193i according to the third embodiment fills the inside of the cutout in the planarization layer 130 on which the end 174a extends along the inclined surface 130c. The lower surface of the filling portion 193i is in contact with the hole bottom 132a. As described above, in the cutout (e.g., the cutout CRG) in the bank 193, the lower surface of the bank 193 is in contact with the upper surface of the first planarization layer (planarization layer 132) exposed in the hole (hole H) of the bank 193. In the example illustrated in FIG. 18, the position of a cutout bottom 193j serving as the upper surface of the filling portion 193i is the same as that of the upper surface of pixel electrodes 174.

An end Rf of the organic EL layer 137R according to the third embodiment extends along the cutout bottom 193j to the cutout CRG. Therefore, the organic EL layer 137R according to the third embodiment has the end Rf instead of the extending portion Rc described above. An end Gf of the organic EL layer 137G extends along the cutout bottom 193j to the cutout CRG. Therefore, the organic EL layer 137G according to the third embodiment has the end Gf instead of the extending portion Gc described above. The end Rf and the end Gf are separated and face each other in the first direction Dx.

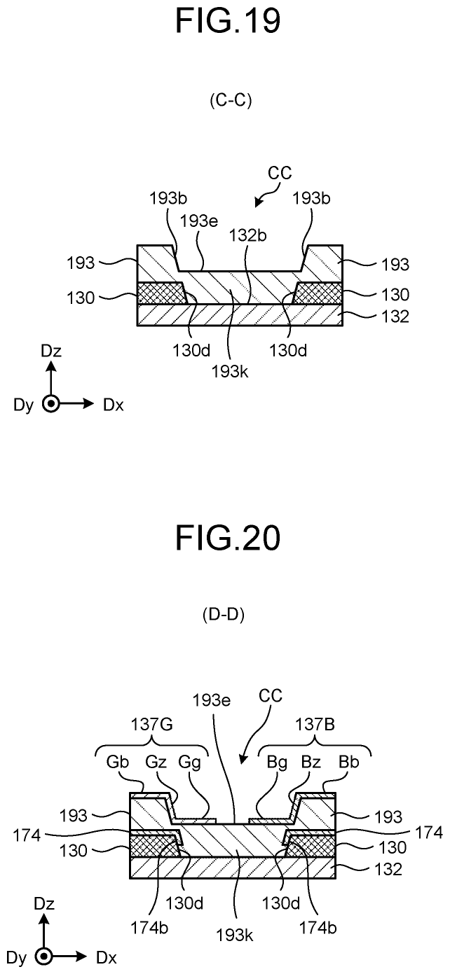

FIG. 19 is a sectional view along line C-C according to the third embodiment. FIG. 20 is a sectional view along line D-D according to the third embodiment. The planarization layer 130 according to the third embodiment is shaped to be cut out downward at the position of the cutout CC. The side surface of the planarization layer 130 shaped in this manner is an inclined surface 130d that makes an obtuse angle with the upper surface of the planarization layer 130 and an acute angle with the lower surface of the planarization layer 130. In the example illustrated in FIGS. 19 and 20, the planarization layer 130 is shaped to form a hole bottom 132b where the planarization layer 130 covering the upper surface of the planarization layer 132 is not stacked in the cutout CC.

A filling portion 193k according to the third embodiment fills the inside of the inclined surfaces 130d. In the example illustrated in FIGS. 19 and 20, the covering portion 193e of the filling portion 193k is higher than the position of the upper surface of the planarization layer 130 and lower than the position of the upper surface of the bank 193. The covering portion 193e is continuous with the lower ends of the two inclined surfaces 193b facing each other in the first direction Dx with the cutout CC therebetween.

In the third embodiment, as illustrated in FIG. 20, ends 174b of the two pixel electrodes 174 facing each other in the first direction Dx with the cutout CC therebetween are each formed to incline downward along the inclined surface 130d. In the example illustrated in FIG. 20, the lower end of the end 174b does not reach the hole bottom 132b.

An end Gg of the organic EL layer 137G according to the third embodiment extends along the covering portion 193e to the cutout CC. Therefore, the organic EL layer 137G according to the third embodiment has the end Gg instead of the extending portion Gd described above. The end Gg is continuous with the extending portion Gb via the relay portion Gz. An end Bg of the organic EL layer 137B according to the third embodiment extends along the covering portion 193e to the cutout CC. Therefore, the organic EL layer 137B according to the third embodiment has the end Bg instead of the extending portion Bd described above. The end Bg is continuous with the extending portion Bb via the relay portion Bz. The end Gg and the end Bg are separated and face each other in the first direction Dx.

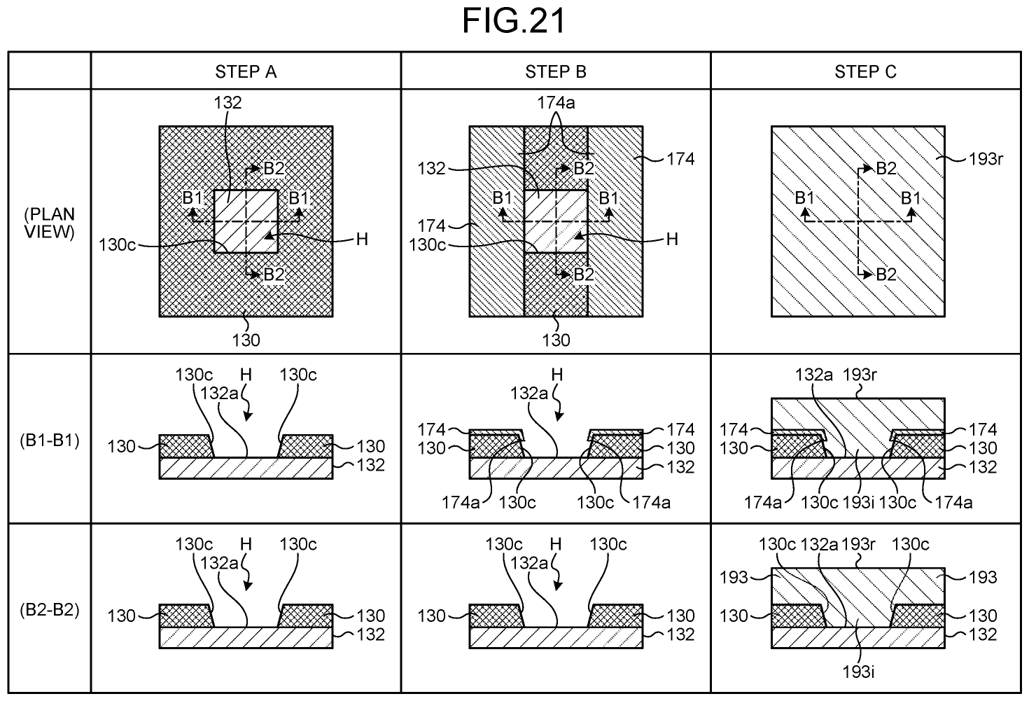

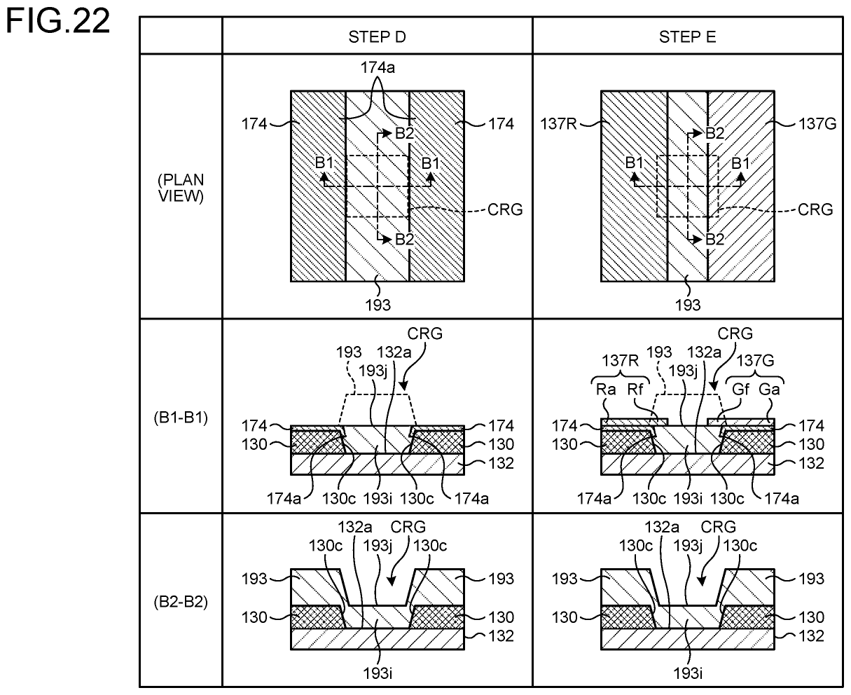

The following describes an example of formation of the multilayered structure in the cutout CRG according to the third embodiment with reference to FIGS. 21 and 22. FIGS. 21 and 22 are process diagrams illustrating the steps for processing the components stacked on the lower planarization layer 132. FIGS. 21 and 22 illustrate a plan view, a B1-B1 sectional view, and a B2-B2 sectional view in parallel. The plan view is a view of the area around the cutout CRG when viewed from above. The B1-B1 sectional view illustrates the multilayered structure at the same position as that of the B-B sectional view described above. The B2-B2 sectional view illustrates the Dy-Dz section orthogonal to the B1-B1 section in the cutout CRG.

Step A in FIG. 21 indicates the state where the planarization layer 130 stacked on the upper side of the planarization layer 132 is cut out such that the rectangular hole H is formed in plan view. As a result, the hole bottom 132a and the inclined surfaces 130c are formed to face the hole H.

Step B in FIG. 21 indicates the state where the pixel electrodes 174 are formed to be stacked on the upper side of the planarization layer 130. The pixel electrodes 174 are formed such that the ends 174a of the two pixel electrodes 174 facing each other in the first direction Dx with the hole H therebetween extend into the hole H. As a result, the ends 174a are formed to incline downward along the inclined surfaces 130c. The hole H is a hole formed by digging the second planarization layer (planarization layer 130) serving as the upper planarization layer of the two planarization layers 130 and 132 stacked on the lower side of the pixel electrodes 174 toward the first planarization layer (planarization layer 132) serving as the lower planarization layer. The cutout (e.g., the cutout CRG) in the bank 193 is formed at the position overlapping the hole (hole H) in the second planarization layer.

Step C in FIG. 21 indicates the state where the bank layer 193r to be formed into the bank 193, the filling portion 193i, and the filling portion 193k described above is formed on the upper side of the pixel electrodes 174 formed at Step B. As illustrated in Step C, the bank layer 193r entirely covers the pixel electrodes 174, the planarization layer 130, and the hole bottom 132a the upper surface of which is exposed at the previous steps.

Step D in FIG. 22 indicates the state where the bank layer 193r formed at Step C in FIG. 21 is shaped to form the grid-shaped bank 193 (refer to FIG. 2), the filling portion 193i, and the filling portion 193k described above. The filling portion 193i is left on the upper side of the hole bottom 132a to fill the hole H at Step D, and the cutout bottom 193j is shaped along the upper surface of the pixel electrodes 174. As a result, the cutout CRG having a shape obtained by cutting out the bank 193 along the second direction Dy is formed as indicated in the B2-B2 point of view. The filling portion 193i corresponds to the polymeric material layer stacked on the upper side of the hole H.

Step E in FIG. 22 indicates the state where the organic EL layer 137R and the organic EL layer 137G are formed on the upper side of the layered body illustrated in Step D. By advancing the process to this state, the B1-B1 section becomes the same as the B-B sectional structure described with reference to FIG. 18. The process for stacking the organic EL layer 137R and the organic EL layer 137G may be performed by the additive method like the process described with reference to Steps 5, 6, and 7 in FIG. 8 and Step 8 in FIG. 9 according to the first embodiment or by the subtractive method.

The process for forming the filling portion 193k according to the third embodiment in the C-C section described with reference to FIG. 19 is substantially the same as the process for the B2-B2 section described with reference to FIGS. 21 and 22. The process for forming the ends 174b in the D-D section described with reference to FIG. 20 is substantially the same as the process of forming the ends 174a in the B1-B1 section described with reference to FIG. 21. The organic EL layer 137B, which is not illustrated, is naturally formed in the third embodiment. The organic EL layers 137R, 137G, and 137B simply need to be formed after Step D and before the stacking of the common electrode 138.

The Dx-Dz sectional view of the cutout CGB (refer to FIG. 2) according to the third embodiment is the same as the sectional view obtained by replacing the organic EL layer 137R illustrated in FIG. 18 with the organic EL layer 137G and replacing the organic EL layer 137G with the organic EL layer 137B. The Dx-Dz sectional view of the configuration at and near the cutout CB (refer to FIG. 2) according to the third embodiment is the same as the sectional view obtained by replacing the organic EL layer 137R illustrated in FIG. 18 with the organic EL layer 137B and replacing the organic EL layer 137G with the organic EL layer 137R. The Dy-Dz section of the cutout CRR (refer to FIG. 2) according to the third embodiment is the same as the section obtained by replacing the organic EL layer 137G illustrated in FIG. 18 with the organic EL layer 137R and replacing the first direction Dx and the second direction Dy with each other. Except for the items noted above, the third embodiment is the same as the first embodiment.

The planarization layer according to the third embodiment includes the first planarization layer (planarization layer 132) and the second planarization layer (planarization layer 130) provided on the first planarization layer. The electrodes (pixel electrodes 174) are provided on the second planarization layer. The second planarization layer has the hole (hole H) at the position overlapping the cutout (e.g., the cutouts CRG, CGB, CB, CRR, and CC). With this configuration, the filling portion 193i and the filling portion 193k can be a polymeric material layer stacked in the hole (hole H). As in the second embodiment, this configuration enables both reducing occurrence of a short circuit between the pixel electrode 174 and the common electrode 138 and readily removing the residual solution remaining after washing.

In the cutout (e.g., the cutouts CRG, CGB, CB, CRR, and CC) in the bank 193, the lower surface of the bank 193 is in contact with the upper surface of the first planarization layer (planarization layer 132) exposed in the hole (hole H) of the bank 193. Therefore, the hole H can be formed in a simpler manner without requiring an additional process, such as halftone.

In addition, the hole H can be formed simultaneously with the formation of the contact hole 131. Therefore, an additional process is not required to form the structure according to the third embodiment. This is more advantageous in terms of the manufacturing time and cost of the display device 100.

In addition, reducing the width of the ends 174a and 174b extending in the first direction Dx makes it possible to facilitate making the gap between the sub-pixels smaller in the first direction Dx. This is advantageous in terms of higher resolution and higher aperture ratio of the sub-pixels.

### Modification of the Third Embodiment

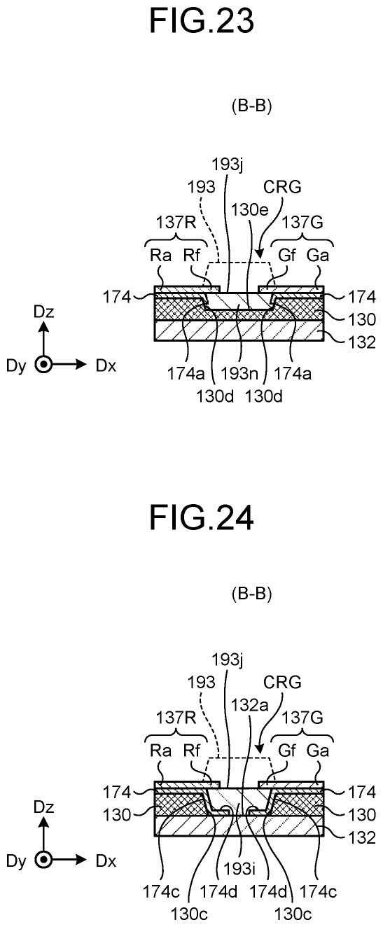

The following describes a modification of the third embodiment with reference to FIGS. 23 and 24.

### First Modification of the Third Embodiment

FIG. 23 is a sectional view along line B-B according to a first modification of the third embodiment. In the following description, when simply referring to “first modification”, it means the first modification of the third embodiment.

In the first modification, the inclined surface 130c in the cutout CRG according to the third embodiment is replaced by an inclined surface 130d. In the first modification, a cutout bottom 130e is formed. The lower end of the inclined surface 130d does not reach the planarization layer 132 and is continuous with the cutout bottom 130e. The cutout bottom 130e covers the upper surface of the planarization layer 132 in the cutout CRG. Therefore, the hole bottom 132a according to the third embodiment is not formed in the first modification. The cutout bottom 130e is formed by using halftone corresponding to the cutout bottom 130e in photolithography, for example.

The filling portion 193i that fills the inside of the inclined surfaces 130c in the cutout CRG according to the third embodiment, is replaced by a filling portion 193n that fills the inside of the inclined surfaces 130d in the cutout CRG. The filling portion 193n is the same as the filling portion 193i except that the component stacked on the lower side of the filling portion 193n is the cutout bottom 130e and that the filling portion 193n is thinner in the third direction Dz than the filling portion 193i corresponding to the thickness of the cutout bottom 130e in the third direction Dz. As described above, the hole (hole H) according to the first modification is filled with the filling portion 193n formed in the same layer as the bank 193 based on the bank layer 193r. The cutout (e.g., the cutout CRG) in the bank 193 is formed by the hole, and the filling portion 193n in the hole is in contact with the upper surface (cutout bottom 130e) of the second planarization layer (planarization layer 130) provided to the bottom surface of the hole.

The first modification can reduce formation of voids when the bank layer 193r is filled into the hole H.

### Second Modification of the Third Embodiment

FIG. 24 is a sectional view along line B-B according to a second modification of the third embodiment. In the following description, when simply referring to “second modification”, it means the second modification of the third embodiment.

In the second modification, the end 174a according to the third embodiment is replaced by a relay portion 174c and an end 174d. The relay portion 174c is formed by extending the end 174a downward along the inclined surface 130c until it reaches the hole bottom 132a. The end 174d is the end of the pixel electrode 174 in the cutout CRG according to the second modification formed to be continuous with the relay portion 174c and extend along the hole bottom 132a. As described above, the hole (hole H) according to the second modification is filled with the filling portion 193i formed in the same layer as the bank 193 based on the bank layer 193r. The cutout (e.g., the cutout CRG) in the bank 193 is formed by the hole, and the lower surface of the filling portion 193i is in contact with the upper surface of the first planarization layer (planarization layer 132). The two ends 174d facing each other in the first direction Dx in the cutout CRG are separated from each other.

The structure in the B-B section according to the third embodiment can be replaced by either the first modification or the second modification. The same applies to the cutouts CGB, CB, and CRR, and the like. The structure of the end 174b in the D-D section may be replaced by the same structure as the relay portion 174c and the end 174d according to the second modification.

The second modification can reduce formation of voids when the bank layer 193r is filled into the hole H.

### Fourth Embodiment

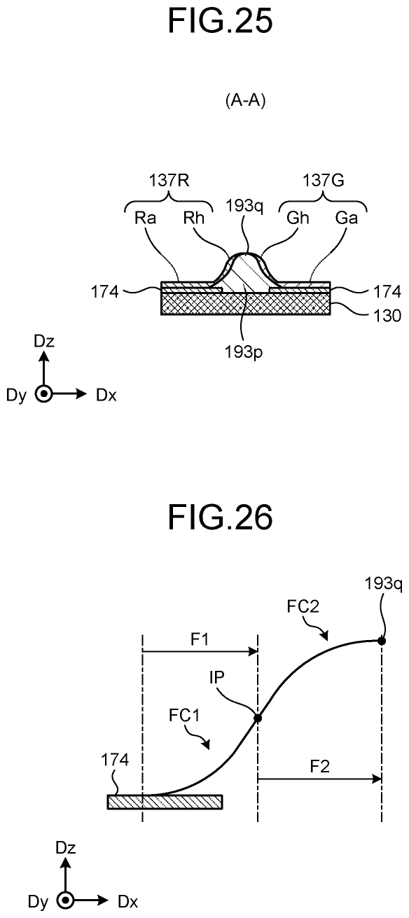

The following describes a fourth embodiment partially different from the first embodiment with reference to FIGS. 25 to 29. In the description of the fourth embodiment, the same components as those according to the first embodiment are denoted by the same reference numerals, and explanation thereof may be omitted.

FIG. 25 is a sectional view along line A-A according to the fourth embodiment. In the fourth embodiment, the bank 193 the sectional shape of which is an isosceles trapezoid according to the first embodiment is replaced by a bank 193the sectional shape of which is represented by a curve including an inflection point IP (refer to FIG. 26). The bank 193p is the same as the bank 193 except that its shape is different from that of the bank 193.

The end of the organic EL layer 137R on the bank 193p side according to the fourth embodiment is an extending portion Rh extending along the curve of the outer shape of the bank 193p. Therefore, the organic EL layer 137R according to the fourth embodiment has the extending portion Rh instead of the extending portion Rb. The end of the organic EL layer 137G on the bank 193p side according to the fourth embodiment is an extending portion Gh extending along the curve of the outer shape of the bank 193p. Therefore, the organic EL layer 137G according to the fourth embodiment has the extending portion Gh instead of the extending portion Gb. The extending portion Rh and the extending portion Gh are separated from each other with an apex 193q of the bank 193p interposed therebetween.

FIG. 26 is a diagram for explaining the curve of the outer shape of the bank 193p according to the fourth embodiment. The curve of the outer shape of the bank 193p includes a first curve FC1 from the lower end on the pixel electrode 174 side to the inflection point IP and a second curve FC2 from the inflection point IP to the apex 193q. In other words, the curve includes the first curve FC1 from the lower surface of the bank 193p to the inflection point IP and the second curve FC2 from the inflection point IP to the upper surface of the bank 193p. The inflection point IP is positioned at a distance F1 along the first direction Dx from a first end of the first curve FC1 in the first direction Dx toward the apex 193q. The inflection point IP is positioned higher than the upper surface of the pixel electrode 174 in the third direction Dz. The apex 193q is positioned at a distance F2 along the first direction Dx from the inflection point IP. The apex 193q is positioned higher than the infection point IP in the third direction Dz. The first curve FC1 is a curve having a positive second derivative (protruding downward) from the first end in the first direction Dx toward the apex 193q. The second curve FC2 is a curve having a negative second derivative (protruding upward) from the first end in the first direction Dx toward the apex 193q. The inflection point IP corresponds to the position where the second derivative is 0 between the first curve FC1 and the second curve FC2.

The curved structure of the bank 193p is formed by using halftone corresponding to the bank 193p in photolithography, for example.

Before explaining the advantageous effects of the shape of the bank 193p described with reference to FIGS. 25 and 26, the following describes the bank 193 according to a comparative example in greater detail.

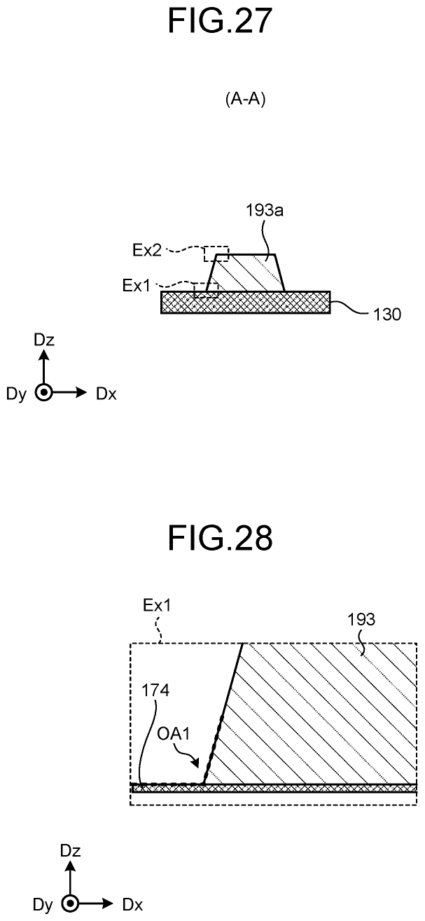

FIG. 27 is a schematic view of the bank 193 according to the comparative example. FIG. 28 is an enlarged view of a first part Ex1 of FIG. 27. FIG. 29 is an enlarged view of a second part Ex2 of FIG. 27. As illustrated in FIGS. 27 and 28, the bank 193 forms a corner OA1 with the planarization layer 130 provided on the lower side of the bank 193. If a solution, such as the solution SOL (refer to FIG. 11), adheres to this part, even with the biasing force of the airflow AB (refer to FIG. 11) or the like, it tends to take some time to completely remove the solution. If the direction of the airflow is opposite to that of the airflow AB (refer to FIG. 11), the solution, such as the solution SOL (refer to FIG. 11), adhering to the corner OA1 tends to be less subject to the biasing force of the airflow in the opposite direction.

To address this, the outer shape of the bank 193p according to the fourth embodiment is curved as described above with reference to FIGS. 25 and 26 to prevent the corner OA1 (refer to FIG. 28) from being formed. With this configuration, if a solution, such as the solution SOL (refer to FIG. 11), adheres to a portion near the contact position between the bank 193p and the pixel electrode 174, the biasing force from the air knife or the like can satisfactorily blow away and remove the solution. As illustrated in FIG. 29, a shape OA2 near the end of the short side of the bank 193 in the first direction Dx according to the first embodiment is slightly rounded. By contrast, the bank 193p according to the fourth embodiment is more significantly curved continuously from the pixel electrode 174 to the apex 193q via the inflection point IP, thereby facilitating movement of the solution, such as the solution SOL (refer to FIG. 11), along the curved surface. Therefore, the fourth embodiment enables more satisfactorily performing the removal process in a shorter time.

The configuration of fourth embodiment does not necessarily have the cutouts, such as the cutouts CRG, CGB, CB, CRR, and CC described above. Needless to say, the first embodiment, the second embodiment, the third embodiment, or either of the modifications of the third embodiment may be combined with the fourth embodiment to form one or more of the cutouts CRG, CGB, CB, CRR and CC in the bank 193p according to the fourth embodiment. If such a combination is made, the inclined surface 193b described above may be a curve similar to the curve of the outer shape of the bank 193p.

According to the fourth embodiment combined with the first embodiment, the second embodiment, the third embodiment, or either of the modifications of the third embodiment, the side surface of the grid formed by the bank 193p is a curve including the inflection point IP in sectional view. As a result, the residual solution remaining after washing is more likely to move along the curved surface of the bank 193p. Therefore, the residual solution remaining after washing can be more readily removed.

The configuration of the fourth embodiment not combined with the first embodiment, the second embodiment, the third embodiment, or either of the modifications of the third embodiment includes the substrate (array substrate 120), the electrodes (pixel electrodes 174), the bank 193, and the light-emitting layers (the organic EL layer 137R, the organic EL layer 137G, and the organic EL layer 137B). The electrodes are arrayed in the first direction Dx and the second direction Dy. The bank 193 protrudes with respect to the electrodes in the third direction Dz orthogonal to the first direction Dx and the second direction Dy and surrounds each of the electrodes to form a grid. The light-emitting layers are stacked on the electrodes. The bank 193p forms a grid surrounding the area of contact between the pixel electrode 174 and the light-emitting layer (e.g., the base portions Ra, Ga, and Ba). The side surface of the grid is a curve including the inflection point IP in sectional view. As a result, the residual solution remaining after washing is more likely to move along the curved surface of the bank 193p. Therefore, the residual solution remaining after washing can be more readily removed.

Regardless of whether the fourth embodiment is combined with the first embodiment, the second embodiment, the third embodiment, or either of the modifications of the third embodiment, the curve according to the fourth embodiment includes the first curve FC1 from the lower surface of the bank 193p to the inflection point IP and the second curve FC2 from inflection point IP to the upper surface of the bank 193p. The first curve FC1 is a curve with a positive second derivative. The second curve FC2 is a curve with a negative second derivative. As a result, the curved surface of the bank 193p on which the residual solution remaining after washing is more likely to move can be formed in a simpler manner.

### Fifth Embodiment

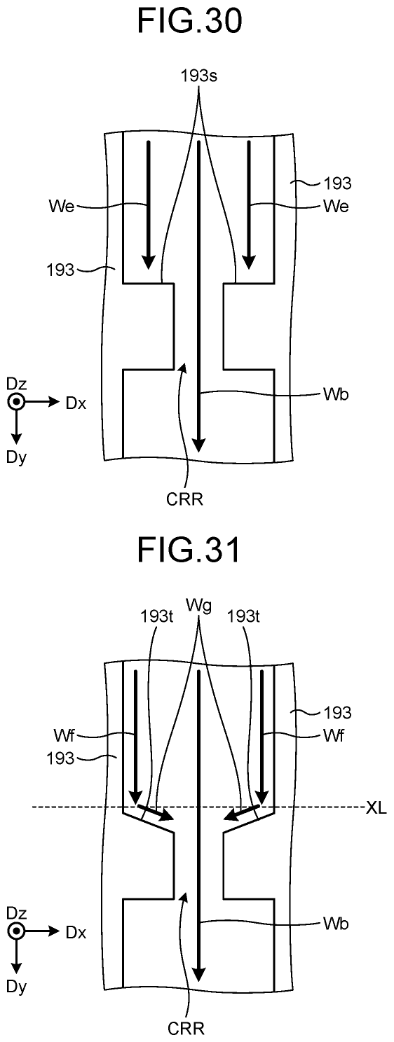

The following describes a fifth embodiment partially different from the first embodiment with reference to FIGS. 30 to 33. In the description of the fifth embodiment, the same components as those according to the first embodiment are denoted by the same reference numerals, and explanation thereof may be omitted.

Before explaining the fifth embodiment, the following describes the structure at and near the cutout CRR according to a comparative example in greater detail. FIG. 30 is a plan view of an example of the structure at and near the cutout CRR according to the comparative example in Dx-Dy plane view.

As illustrated in FIG. 30, the cutout CRR is formed so as to form ends 193s of the bank 193 facing each other in the first direction Dx with the cutout CRR therebetween. The end 193s has wall surfaces along the first direction Dx. The cutout CRR allows the solution at a position where it can pass directly through the cutout CRR to satisfactorily pass therethrough as indicated by the arrow Wb. By contrast, the solutions at positions where the solutions collide with the wall surfaces along the first direction Dx of the end 193s as indicated by the arrow We may take some time to join the flow at the position indicated by the arrow Wb.

FIG. 31 is a plan view of an example of the structure at and near the cutout CRR according to the fifth embodiment in Dx-Dy plane view. In the fifth embodiment, one or more of the side surfaces of ends 193t facing each other in the first direction Dx with the cutout CRR therebetween are inclined surfaces making an obtuse angle with the cutout CRR in Dx-Dy plane view. FIG. 31 illustrates the inclination of the ends 193t with respect to the reference line XL extending along the first direction Dx.

In FIG. 31, the inclined surfaces are the surfaces on the upstream of the biasing force applied by the configuration used in the removal process, such as the air knife. As a result, the flow path extending from the upstream of the cutout CRR to the cutout CRR has a funnel shape from upstream toward downstream in Dx-Dy plane view. In other words, the inclined surfaces serve as wall surfaces that spread widely from the downstream toward the upstream of the flow generated by the biasing force applied to a liquid used in the stacking process of at least one or more of the pixel electrodes 174, the bank 193, and the light-emitting layers (e.g., the organic EL layer 137R, the organic EL layer 137G, and the organic EL layer 137B), wherein the biasing force is applied by an external machine that removes the liquid. Therefore, the solution at the position where the solution collides with the end 193t as indicated by the arrow Wf is guided along the arrow Wg in the direction of joining the arrow Wb by the inclined surface. As a result, the solution, such as the solution SOL (refer to FIG. 11), is more likely to move along the inclined surface. Therefore, the fifth embodiment enables more satisfactorily performing the removal process in a shorter time.

As described above, in the fifth embodiment, the ends of the bank 193 facing each other with the cutout (e.g., the cutout CRR) therebetween incline with respect to the first direction Dx and the second direction Dy like the ends 193t, for example. In other words, the bank 193 has inclined surfaces formed such that the width of the bank 193 decreases toward the cutout (e.g., the cutout CRR) in the bank 193 in plan view. While the surfaces on the downstream are not inclined surfaces in FIG. 31, they may also be inclined surfaces that make an obtuse angle with the cutout CRR in Dx-Dy plane view. The inclined surfaces may be provided not only to the cutout CRR but also to the other cutouts based on the same concept.

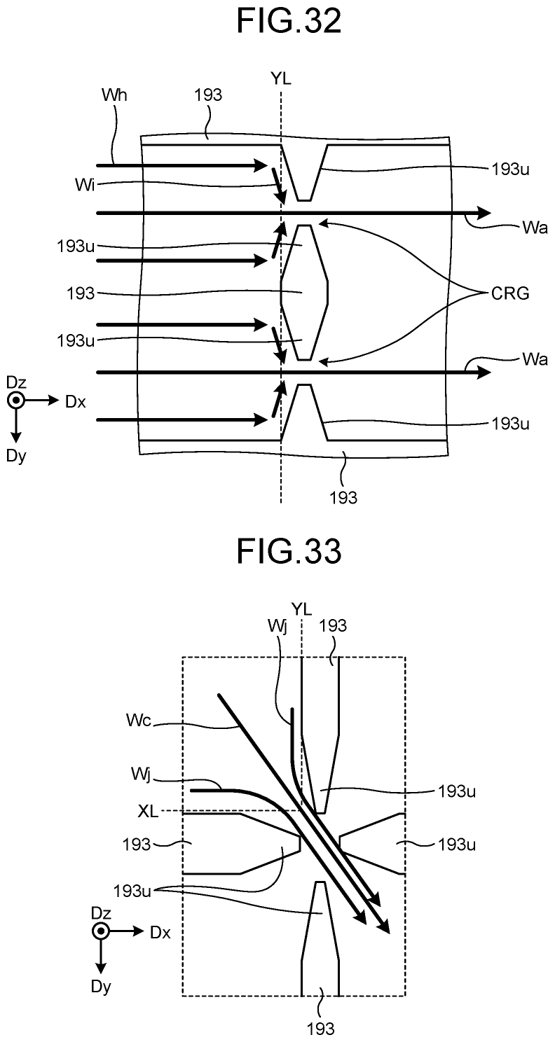

FIG. 32 is a plan view of an example of the structure at and near the cutout CRG according to the fifth embodiment in Dx-Dy plane view. FIG. 32 illustrates the inclination of ends 193u with respect to the reference line YL extending along the second direction Dy. As illustrated in FIG. 32, the ends 193u of the bank 193 facing each other with the cutout CRG therebetween are formed in a tapered shape. As a result, the flow path extending from the upstream of the cutout CRG to the cutout CRG indicated by the arrow Wa has a funnel shape from upstream toward downstream in Dx-Dy plane view. Therefore, the solution at the position where the solution collides with the end 193u as indicated by the arrow Wh is guided along the arrow Wi in the direction of joining the arrow Wa by the inclined surface. As a result, the solution, such as the solution SOL (refer to FIG. 11), is more likely to move along the inclined surface. Therefore, the fifth embodiment enables more satisfactorily performing the removal process in a shorter time. With the structure illustrated in FIG. 32, the flow path has a funnel shape from upstream toward downstream in Dx-Dy plane view if the biasing force applied to the solution by the air knife or the like is in the direction opposite to the arrow Wa.

The same tapered structure as that of the ends 193u illustrated in FIG. 32 can be applied to the ends of the bank 193 facing each other with the cutout CGB or the cutout CB therebetween.

FIG. 33 is a plan view of an example of the structure at and near the cutout CC according to the fifth embodiment in Dx-Dy plane view. As illustrated in FIG. 33, the ends 193u of the bank 193 facing each other in the first direction Dx or the second direction Dy with the cutout CC therebetween are formed in a tapered shape. As a result, the flow path extending from the upstream of the cutout CC to the cutout CC indicated by the arrow Wc has a funnel shape from upstream toward downstream in Dx-Dy plane view. Therefore, the solution at the position where it collides with the end 193u as indicated by the arrow Wj is guided to join the arrow Wc by the inclined surface. As a result, the solution, such as the solution SOL (refer to FIG. 11), is more likely to move along the inclined surface. Therefore, the fifth embodiment enables more satisfactorily performing the removal process in a shorter time. If the biasing force applied to the solution by the air knife or the like is in the direction other than the arrow Wc, the structure illustrated in FIG. 33 can handle the flow in more directions.

Except for the items noted above, the fifth embodiment may be the same as the first embodiment. The fifth embodiment may be combined with the second embodiment, the third embodiment, or either of the modifications of the third embodiment. When the fourth embodiment is combined with the first embodiment, the second embodiment, the third embodiment, or either of the modifications of the third embodiment, the fifth embodiment may also be combined with them.

The bank 193 according to the fifth embodiment has inclined surfaces formed such that the width of the bank 193 decreases toward the cutout (e.g., the cutouts CRG, CGB, CB, CRR, and CC) in the bank 193 in plan view. As a result, the residual solution remaining after washing is more likely to move along the inclined surfaces. Therefore, the residual solution remaining after washing can be more readily removed.

The inclined surfaces serve as wall surfaces that spread widely from the downstream toward the upstream of the flow generated by the biasing force applied to a liquid used in the stacking process of at least one or more of the pixel electrodes 174, the bank 193, and the light-emitting layers (e.g., the organic EL layer 137R, the organic EL layer 137G, and the organic EL layer 137B), wherein the biasing force is applied by an external machine that removes the liquid. Therefore, the residual solution remaining after washing can be more readily removed by the biasing force.

Out of the other advantageous effects achieved by the aspects described in the embodiments above, advantageous effects clearly defined by the description in the present specification or appropriately conceivable by those skilled in the art are naturally achieved by the present disclosure.

What is claimed is:

1. A display device comprises:
a substrate;
a planarization layer provided on the substrate;
a plurality of electrodes provided on the planarization layer and arrayed in a first direction and a second direction;
a bank provided on the planarization layer and the electrodes and formed in a grid pattern so as to surround each of the electrodes; and
a light-emitting layer provided on the electrodes, wherein
the bank protrudes with respect to the electrodes in a third direction orthogonal to the first direction and the second direction, and
a cutout is formed in part of the bank.

2. The display device according to claim 1, wherein the planarization layer is exposed at a bottom of the cutout in the bank.

3. The display device according to claim 1, wherein the thickness of the bank from the planarization layer to an upper surface of the bank in the cutout is less than the thickness of the bank from the planarization layer to the upper surface of the bank at a position where the cutout is not formed.

4. The display device according to claim 1, wherein
the planarization layer comprises a first planarization layer and a second planarization layer provided on the first planarization layer,
the electrodes are provided on the second planarization layer, and
the second planarization layer has a hole at a position overlapping the cutout.

5. The display device according to claim 4, wherein
the hole is filled with the bank,
the cutout in the bank is formed by the hole, and
a lower surface of the bank in the hole is in contact with an upper surface of the second planarization layer provided to a bottom surface of the hole.

6. The display device according to claim 5, wherein an end of each of the electrodes partially covers an edge of the hole in the second planarization layer.

7. The display device according to claim 4, wherein
the hole is filled with the bank,
the cutout in the bank is formed by the hole, and
a lower surface of the bank is in contact with an upper surface of the first planarization layer in the cutout in the bank.

8. The display device according to claim 7, wherein an end of each of the electrodes partially covers an edge of the hole in the second planarization layer and extends to the upper surface of the first planarization layer.

9. The display device according to claim 1, wherein the bank has an inclined surface formed such that the width of the bank decreases toward the cutout in the bank in plan view.

10. The display device according to claim 1, wherein the cutout is formed at a corner of the grid in plan view.

11. The display device according to claim 1, further comprising:
a first pixel, a second pixel, and a third pixel adjacently disposed in the first direction, wherein
a first cutout in the bank between the first pixel and the second pixel and a second cutout in the bank between the second pixel and the third pixel are arranged in a line.

12. The display device according to claim 11, further comprising:
a fourth pixel and a fifth pixel, wherein
the first pixel, the fourth pixel, and the fifth pixel are adjacently disposed in the second direction, and
a third cutout in the bank between the first pixel and the fourth pixel and a fourth cutout in the bank between the fourth pixel and the fifth pixel are arranged in a line.

13. The display device according to claim 1, wherein a side surface of the grid is a curve including an inflection point in sectional view.

14. A method for manufacturing an organic electroluminescent display panel comprising a planarization layer formed on a substrate, a plurality of electrodes formed on the planarization layer, a bank formed on the planarization layer and each of the electrodes and formed in a grid pattern so as to surround each of the electrodes, and an organic EL layer formed on the electrodes, the method comprising:
patterning by photolithography such that a cutout is formed in part of the bank in a display region in which the electrodes are formed;
removing a resist layer in an area where the organic EL layer is to be formed, by immersing the resist layer in a solution; and
removing the solution from the organic electroluminescent display panel, wherein
compressed air is emitted so as to blow away the solution at the removing the solution, and
the cutout is formed along a direction of emission of the compressed air.

15. The method for manufacturing an organic electroluminescent display panel according to claim 14, wherein
the electrodes are arrayed in a first direction and a second direction, and
a plurality of the cutouts are formed along the first direction or the second direction.

16. The method for manufacturing an organic electroluminescent display panel according to claim 14, wherein the cutout is formed at a corner of the grid.
